(19) United States
(12) Patent Application Publication
(10) Pub. No.: US 2026/0090249 A1
(43) Pub. Date: Mar. 26, 2026

(54) TRANSPARENT DISPLAY APPARATUS

(71) Applicant: LG Display Co., Ltd., Seoul (KR)

(72) Inventors: Choonghyo KIM, Paju-si (KR); Hoiyong KWON, Paju-si (KR); JiHun SONG, Paju-si (KR)

(73) Assignee: LG Display Co., Ltd., Seoul (KR)

(21) Appl. No.: 19/270,993

(22) Filed: Jul. 16, 2025

(30) Foreign Application Priority Data
Sep. 20, 2024 (KR) 10-2024-0127489

(51) Int. Cl. H10K 59/80; H10K 59/121; H10K 59/122; H10K 59/123; H10K 59/38; H10K 59/88; H10K 102/00

(52) U.S. Cl. CPC H10K 59/8731; H10K 59/1213; H10K 59/122; H10K 59/123; H10K 59/38; H10K 59/88; H10K 2102/351

(57) ABSTRACT

A transparent display apparatus according to one or more examples may include a substrate, a transmissive area, a non-transmissive area including a light emission area in which a light emitting element is disposed, a circuit layer on the substrate, the circuit layer having an auxiliary power electrode disposed in the transmissive area and at least one thin film transistor disposed in the non-transmissive area, a plurality of inorganic protective layers and a plurality of organic protective layers on the circuit layer, and an undercut structure including at least one undercut region formed by a lower inorganic protective layer and an upper organic protective layer, which are adjacent to each other among the plurality of inorganic protective layers and the plurality of organic protective layers.

### CROSS-REFERENCE TO RELATED APPLICATIONS

This application claims the benefit of and priority to Korean Patent Application No. 10-2024-0127489 filed in Republic of Korea on Sep. 20, 2024, the entire contents of which are incorporated herein by reference for all purposes.

### BACKGROUND

### 1. Technical Field

The present disclosure relates to a transparent display apparatus.

### 2. Description of the Related Art

With the advancement of the information age, the demand for a display apparatus for displaying an image has increased in various forms. Therefore, various types of display apparatuses such as a liquid crystal display (LCD) apparatus, an organic light emitting display (OLED) apparatus, a micro light emitting diode (LED) display apparatus and a quantum dot display (QD) apparatus have been recently used.

Recently, studies for a transparent display apparatus that displays an image for a user and allows the user to view objects or images, which are positioned at an opposite side thereof, by transmitting light are actively ongoing. The transparent display apparatus includes a display area, on which an image is displayed, and a non-display area, wherein the display area may include a transmissive area capable of transmitting external light and a non-transmissive area. The transparent display apparatus may have high light transmittance in the display area through the transmissive area.

The transparent display apparatus mainly employs a top emission type in which light is emitted in an upward direction. The transparent display apparatus may be configured by bonding a lower substrate (or an array substrate), on which pixels emitting light to display an image are arranged, and an upper substrate (or a color filter substrate), on which color filters corresponding to the respective pixels are arranged. However, during the bonding process of the lower and upper substrates, non-uniformity in the cell gap may occur due to a pressing phenomenon caused by internal foreign substances. As a result, defects such as dark spots may occur, leading to deterioration in image quality.

The description of the related art should not be assumed to be prior art merely because it is mentioned in or associated with this section. The description of the related art includes information that describes one or more aspects of the subject technology, and the description in this section does not limit the invention.

### SUMMARY

One or more embodiments of the present disclosure may provide a transparent display apparatus having a cathode contact structure capable of maintaining uniformity in the cell gap.

One or more embodiments of the present disclosure may provide a transparent display apparatus capable of enhancing the light extraction efficiency of a light emitting element while ensuring high light transmittance.

One or more embodiments of the present disclosure may provide a transparent display apparatus capable of preventing defect propagation caused by a gap spacer while maintaining uniformity in the cell gap.

Additional advantages and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

A transparent display apparatus according to one or more embodiments of the present disclosure may include a substrate, a transmissive area, a non-transmissive area including a light emission area in which a light emitting element is disposed, a circuit layer on the substrate, the circuit layer having an auxiliary power electrode disposed in the transmissive area and at least one thin film transistor disposed in the non-transmissive area, a plurality of inorganic protective layers and a plurality of organic protective layers on the circuit layer, and an undercut structure including at least one undercut region formed by a lower inorganic protective layer and an upper organic protective layer, which are adjacent to each other among the plurality of inorganic protective layers and the plurality of organic protective layers.

According to one or more embodiments of the present disclosure, a transparent display apparatus having a cathode contact structure capable of maintaining uniformity in the cell gap may be provided.

According to one or more embodiments of the present disclosure, a transparent display apparatus capable of enhancing the light extraction efficiency of a light emitting element while ensuring high light transmittance may be provided.

According to one or more embodiments of the present disclosure, a transparent display apparatus capable of preventing defect propagation caused by a gap spacer while maintaining uniformity in the cell gap may be provided.

The transparent display apparatus according to one or more embodiments of the present disclosure may reduce defects occurring in a manufacturing process through a gap spacer that maintains uniformity in the cell gap, thereby improving production yield and reliability, whereby it is possible to implement Environment/Social/Governance (ESG) by reducing the generation of greenhouse gas that may occur due to the manufacturing process.

The effects of the present disclosure are not limited to the aforesaid, but other effects not described herein will be clearly understood by those skilled in the art from the following descriptions.

The details of the present disclosure described in technical problem, technical solution, and advantageous effects do not specify essential features of claims, and thus, the scope of claims is not limited by the details described in detailed description of the invention.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 illustrates a transparent display apparatus according to an embodiment of the present disclosure.

FIG. 2 is a circuit diagram illustrating a subpixel of a transparent display apparatus according to an embodiment of the present disclosure.

FIG. 3 illustrates a region A shown in FIG. 1 according to an embodiment of the present disclosure.

FIG. 4 is a cross-sectional view taken along line I-I′ of FIG. 3 according to an embodiment of the present disclosure.

FIG. 5 is a cross-sectional view taken along line I-I′ of FIG. 3 according to another embodiment of the present disclosure.

FIG. 6 is a cross-sectional view taken along line I-I′ of FIG. 3 according to another embodiment of the present disclosure.

FIG. 7 is a cross-sectional view taken along line I-I′ of FIG. 3 according to another embodiment of the present disclosure.

FIG. 8 is a cross-sectional view taken along line II-II′ of FIG. 3 according to an embodiment of the present disclosure.

FIG. 9 is a cross-sectional view taken along line II-II′ of FIG. 3 according to another embodiment of the present disclosure.

FIG. 10 is a cross-sectional view taken along line II-II′ of FIG. 3 according to another embodiment of the present disclosure.

FIG. 11 is a cross-sectional view taken along line II-II′ of FIG. 3 according to another embodiment of the present disclosure.

FIG. 12 illustrates a region B shown in FIG. 3 according to another embodiment of the present disclosure.

FIG. 13 is a cross-sectional view taken along line III-III′ of FIG. 12 according to another embodiment of the present disclosure.

FIG. 14 illustrates a transparent display apparatus according to another embodiment of the present disclosure.

FIGS. 15 to 18 illustrate a non-display area of a transparent display apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just”or “direct”is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

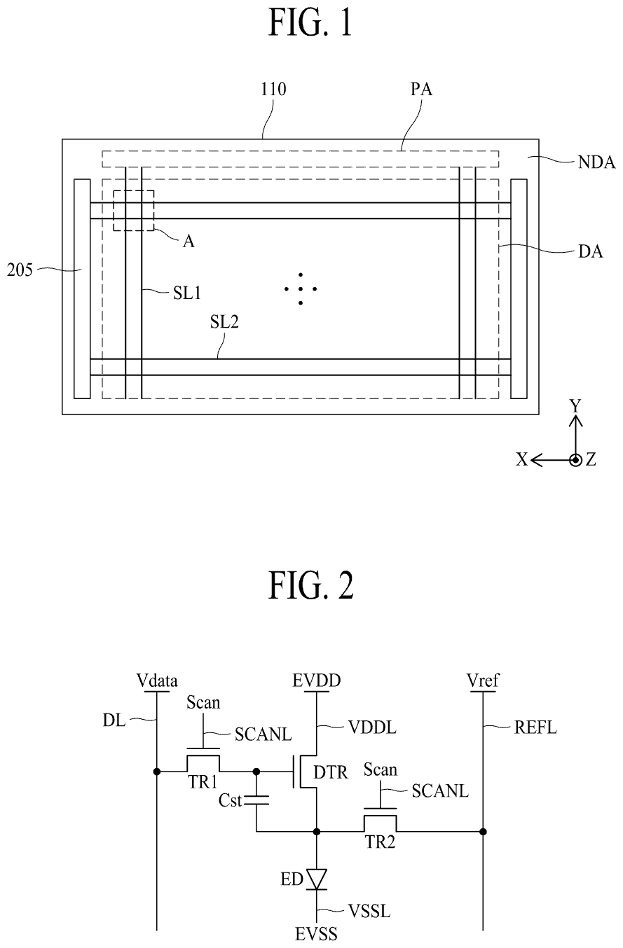

FIG. 1 illustrates a transparent display apparatus according to an embodiment of the present disclosure. FIG. 2 is a circuit diagram illustrating a subpixel of a transparent display apparatus according to an embodiment of the present disclosure.

Hereinafter, X-axis represents a direction parallel with a scan line (or a gate line), Y-axis represents a direction parallel with a data line, and Z-axis represents a height direction of the transparent display apparatus.

Although the transparent display apparatus according to one embodiment of the present disclosure will be described to be implemented as an organic light emitting display (OLED), it may be also implemented as a liquid crystal display (LCD), a micro LED display, a quantum dot display (QD), etc.

Referring to FIGS. 1 and 2, the transparent display apparatus according to one embodiment of the present disclosure may include a transparent display panel 110 that includes a display area DA in which pixels are configured to display an image and a non-display area NDA in which an image is not displayed.

The display area DA of the transparent display panel 110 may include first signal lines SL1, second signal lines SL2 and pixels, and the non-display area NDA thereof may include a pad area PA in which pads are disposed and at least one gate driver 205.

The first signal lines SL1 may extend in a first direction (or Y-axis direction), and may cross the second signal lines SL2 in the display area DA. The second signal lines SL2 may extend in a second direction (or X-axis direction), and may cross the first signal lines SL1 in the display area DA. The pixels may be disposed in an area where the first signal line SL1 and the second signal line SL2 cross each other, and may emit light of predetermined color to display an image.

The gate driver 205 may be connected to the second signal lines SL2. For example, the second signal lines SL2 may include a scan line (or a gate line), and the gate driver 205 may be connected to the scan line (or the gate line) to supply a scan signal. For example, the gate driver 205 may be implemented in a gate driver in panel (GIP) method or a tape automated bonding (TAB) method on the non-display area NDA outside one side or both sides of the display area DA of the transparent display panel 110.

A source drive integrated circuit, a circuit board or a timing controller, which is connected through a flexible circuit film, may be electrically connected to the pad area PA of the transparent display panel 110.

Referring to FIG. 2, each of the pixels may include a plurality of subpixels constituting a unit pixel, and each of the subpixels include a pixel circuit comprising at least one thin film transistor, and a light emitting element ED. For example, the pixel circuit may have a 3T1C structure (three transistors and one capacitor) that includes a first switching transistor TR1, a second switching transistor TR2, a driving transistor DTR, and a storage capacitor Cst, but embodiments of the present disclosure are not limited thereto. For example, the pixel circuit may further include a compensation circuit, and in this case, may have various structures such as 4T2C, 5T2C, 6T1C, 6T2C, 7T1C and 7T2C.

Each of the transistors DTR, TR1 and TR2 of each subpixel may include a gate electrode, a source electrode and a drain electrode. Since the source electrode and the drain electrode are not fixed and may be changed depending on a current direction and a voltage applied to the gate electrode, one of the source electrode and the drain electrode may be expressed as a first electrode (or a first source/drain electrode) and the other one may be expressed as a second electrode (or a second source/drain electrode). The transistors DTR, TR1 and TR2 of each subpixel may use at least one of a polysilicon semiconductor, an amorphous silicon semiconductor or an oxide semiconductor. The transistors DTR, TR1 and TR2 may be P-type or N-type transistors, or P-type and N-type transistors may be used interchangeably.

The first switching transistor TR1 may serve to supply a data voltage Vdata supplied from a data line DL to the driving transistor DTR. For example, the first switching transistor TR1 may charge the storage capacitor Cst with the data voltage Vdata supplied from the data line DL. To this end, the gate electrode of the first switching transistor TR1 may be connected to a scan line SCANL (or a gate line), and a first electrode thereof may be connected to the data line DL. Also, a second electrode of the first switching transistor TR1 may be connected to one end of the storage capacitor Cst and the gate electrode of the driving transistor DTR.

The first switching transistor TR1 may be turned on in response to a scan signal Scan applied through the scan line SCANL (or the gate line). When the first switching transistor TR1 is turned on, the data voltage Vdata applied through the data line DL may be transferred to one end of the storage capacitor Cst.

The second switching transistor TR2 may serve to supply a reference voltage Vref supplied from a reference line REFL to the driving transistor DTR. For example, the gate electrode of the second switching transistor TR2 may be connected to the scan line SCANL (or the gate line), and a first electrode thereof may be connected to the reference line REFL. Also, the second electrode of the second switching transistor TR2 may be connected to a first electrode of the driving transistor DTR and the other end of the storage capacitor Cst.

The second switching transistor TR2 may be turned on in response to the scan signal Scan applied through the scan line SCANL (or the gate line). For example, when the second switching transistor TR2 is turned on, the reference voltage Vref applied through the reference line REFL may be transmitted to the other end of the storage capacitor Cst. Also, the reference voltage Vref may be applied to the source electrode of the driving transistor DTR. For example, when the second switching transistor TR2 is turned on, the voltage at a source node of the driver transistor DTR may be outputted to the reference line REFL.

The storage capacitor Cst may serve to maintain the data voltage Vdata supplied to the driving transistor DTR for one frame. For example, a first electrode of the storage capacitor Cst may be connected to the gate electrode of the driving transistor DTR, and a second electrode thereof may be connected to the source electrode of the driving transistor DTR. The storage capacitor Cst may store a voltage corresponding to the data voltage Vdata transferred through the first switching transistor TR1, and may turn on the driving transistor DTR with the stored voltage.

The driving transistor DTR may generate a data current using a first power voltage EVDD (or a pixel power voltage) supplied from a pixel power source line VDDL (or a first power source line) and supply the generated data current to an anode electrode of the light emitting element ED. For example, the gate electrode of the driving transistor DTR may be connected to one end of the storage capacitor Cst, and the first electrode (or a drain electrode) thereof may be connected to the pixel power source line VDDL. Also, a second electrode (or a source electrode) of the driving transistor DTR may be connected to the anode electrode of the light emitting element ED.

The light emitting element ED may include an anode electrode connected to the driving transistor DTR, a cathode electrode receiving a second power source EVSS (or a common power line) from a common power line VSSL (or a second power line), and a light emitting layer between the anode electrode and the cathode electrode. The anode electrode is an independent electrode for each light emitting element, but the cathode electrode may be a common electrode shared by the entire light emitting elements. When a driving current is supplied from the driving transistor DTR, electrons from the cathode electrode may be injected into the light emitting layer and holes from the anode electrode may be injected into the light emitting layer, so that the light emitting element ED may allow fluorescent or phosphorescent materials to emit light through recombination of the electrons and the holes in the light emitting layer, thereby generating light of brightness proportional to a current value of the driving current.

The anode electrode of the light emitting element ED may be connected to the second electrode of the driving transistor DTR and the cathode electrode thereof may be connected to the common power line VSSL. The light emitting element ED may emit light in response to the driving current generated by the driving transistor DTR.

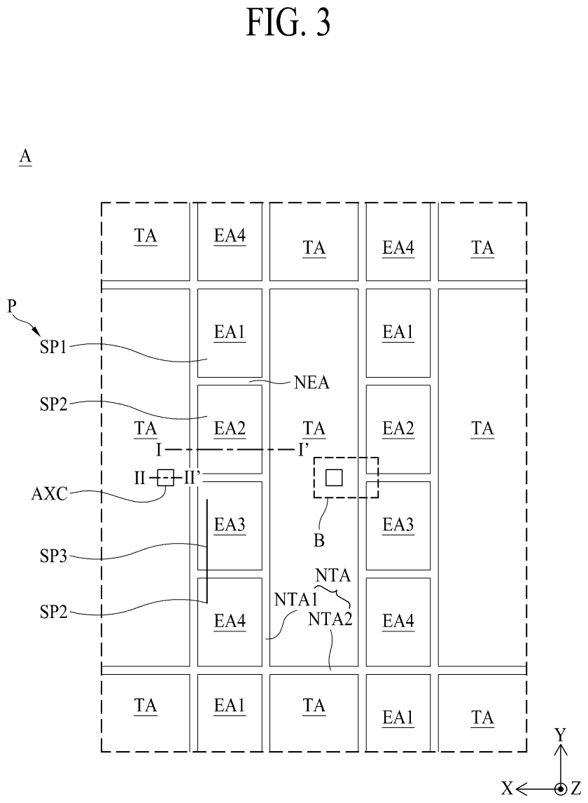

FIG. 3 illustrates a region A shown in FIG. 1 according to an embodiment of the present disclosure.

Referring to FIG. 3 in conjunction with FIGS. 1 and 2, the transparent display panel 110 according to an embodiment of the present disclosure may include a display area DA configured with a plurality of pixels P to display an image, and a non-display area NDA. Each of the plurality of pixels P may include a plurality of subpixels SP1, SP2, SP3 and SP4 that represent different colors.

The display area DA may include a non-transmissive area NTA in which the plurality of subpixels SP1, SP2, SP3 and SP4 are disposed, and a transmissive area TA. The transmissive area TA may be an area that transmits most of light incident from the outside, and the non-transmissive area NTA may be an area that does not transmit most of light incident from the outside. For example, the transmissive area TA may be an area having light transmittance greater than a %, and the non-transmissive area NTA may be an area having light transmittance smaller than b. In this case, a may be a value greater than b. A user may see an object or a background, which is positioned on a back surface (or a rear surface) of the transparent display panel 110, due to the transmissive areas TA.

The non-transmissive area NTA may include a first non-transmissive area NTA1, a second non-transmissive area NTA2 and a plurality of subpixels SP1, SP2, SP3 and SP4.

The first non-transmissive area NTA1 may extend in a first direction (or Y-axis direction) in the transparent display panel 110, and may be disposed to overlap at least a portion of light emission areas EA1, EA2, EA3 and EA4 of each of the plurality of subpixels SP1, SP2, SP3 and SP4.

A plurality of first non-transmissive areas NTA1 may be configured. The plurality of first non-transmissive areas NTA1 may extend in a first direction (or Y-axis direction), and may be disposed to be spaced apart from each other in a second direction (or X-axis direction). Two adjacent first non-transmissive areas NTA1 may be disposed to be spaced apart from each other with the transmissive area TA interposed therebetween. For example, the transmissive area TA may be disposed between the two adjacent first non-transmissive areas NTA1.

At least one first signal line SL1 extending in the first direction (or Y-axis direction) may be disposed in the first non-transmissive area NTA1. For example, the at least one first signal line SL1 may be disposed to overlap the first non-transmissive area NTA1. For example, the at least one first signal line SL1 may include at least one of the pixel power line VDDL (or the first power line), the common power line VSSL (or the second power line), the reference line REFL, and data lines DL, but embodiments of the present disclosure are not limited thereto.

The second non-transmissive area NTA2 may extend in a second direction (or X-axis direction) in the transparent display panel 110, and may be disposed to overlap at least a portion of light emission areas EA1, EA2, EA3 and EA4 of each of the plurality of subpixels SP1, SP2, SP3 and SP4. For example, the second non-transmissive area NTA2 may extend in the second direction (or X-axis direction) between two adjacent first non-transmissive areas NTA1.

A plurality of second non-transmissive areas NTA2 may be configured. The plurality of second non-transmissive areas NTA2 may extend in the second direction (or X-axis direction), and may be disposed to be spaced apart from each other in the first direction (or Y-axis direction). The two adjacent second non-transmissive areas NTA2 may be disposed to be spaced apart from each other with the transmissive area TA interposed therebetween.

At least one second signal line SL2 extending in the second direction (or X-axis direction) may be disposed in the second non-transmissive area NTA2. For example, the at least one second signal line SL2 may be disposed to overlap the second non-transmissive area NTA2. For example, the at least one second signal line SL2 may include a scan line (or a gate line), but embodiments of the present disclosure are not limited thereto.

Each of the pixels P may be disposed in each crossing area where the first non-transmissive area NTA1 and the second non-transmissive area NTA2 cross each other, and may emit light to display an image. Each of the pixels P may include light emission areas EA1, EA2, EA3 and EA4 that emit light in correspondence with the plurality of subpixels SP1, SP2, SP3 and SP4 including a light emitting element ED. The light emission areas EA1, EA2, EA3 and EA4 may correspond to areas, which emit light, in the pixel P. The light emission areas EA1, EA2, EA3 and EA4 may be disposed to overlap a pixel circuits of the plurality of subpixels SP1, SP2, SP3 and SP4. For example, the light emission areas EA1, EA2, EA3 and EA4 may at least partially overlap circuit areas in which the pixel circuits are disposed.

The light emission areas EA1, EA2, EA3 and EA4 may include first to fourth emission areas EA1, EA2, EA3 and EA4 corresponding to each of the plurality of subpixels SP1, SP2, SP3 and SP4. The first to fourth emission areas EA1, EA2, EA3 and EA4 corresponding to the plurality of subpixels SP1, SP2, SP3 and SP4 may emit light of different colors. For example, the first emission area EA1 may emit blue light, the second emission area EA2 may emit red light, the third emission area EA3 may emit green light, and the fourth emission area EA4 may emit white light, but embodiments of the present disclosure are not limited thereto. For example, the plurality of subpixels SP1, SP2, SP3 and SP4 may be configured in a stripe type arranged in the first direction (or Y-axis direction) or a quad type arranged in the first direction and the second direction (or X-axis direction), but not limited thereto. The arrangement order or type of the plurality of subpixels may be variously changed.

The transparent display panel 110 according to an embodiment of the present disclosure may include the light emission areas EA1, EA2, EA3 and EA4 included in each of the plurality of subpixels SP1, SP2, SP3 and SP4, which may include divided light emission areas. For example, each of the plurality of subpixels SP1, SP2, SP3 and SP4 may include a first divided electrode and a second divided electrode, in which a pixel electrode (anode electrode or first electrode) of the light emitting element ED are spaced apart from each other. Each of the first divided electrode and the second divided electrode may correspond to the divided light emission area. For example, the first divided electrode and the second divided electrode may be disposed adjacent to each other in a first direction (or Y-axis direction) or in a second direction (or X-axis direction). According to an embodiment of the present disclosure, each of the plurality of subpixels SP1, SP2, SP3 and SP4 may be configured such that the pixel electrode is divided into a first divided electrode and a second divided electrode, and when particles occur in any one of the first divided electrode and the second divided electrode, an electrical connection between the divided electrode in which particles occur and the pixel circuit may be separated from or disconnected, whereby the divided electrodes may be repaired so that only the divided electrode in which particles occur becomes a dark spot and the remaining divided electrode is normally operated.

The transmissive area TA may be arranged in a first direction (or Y-axis direction) in the transparent display panel 110 and disposed to correspond to each of the pixels P. The transmissive area TA may be disposed adjacent to the plurality of subpixels SP1, SP2, SP3 and SP4 in a second direction (or X-axis direction).

A plurality of transmissive areas TA may be configured. The plurality of transmissive areas TA may be arranged in the first direction (or Y-axis direction), and may be disposed to be spaced apart from each other in the second direction (or X-axis direction). Two adjacent transmissive areas TA in the first direction (or Y-axis direction) may be disposed to be spaced apart from each other the second non-transmissive area NTA2 interposed therebetween. For example, the second non-transmissive area NTA2 may be disposed between the two adjacent transmissive areas TA in the first direction. Two adjacent transmissive areas TA in the second direction (or X-axis direction) may be disposed to be spaced apart from each other the first non-transmissive area NTA1 interposed therebetween. For example, the first non-transmissive area NTA1 may be disposed between the two adjacent transmissive areas TA in the second direction.

An auxiliary power contact portion AXC may be disposed in the transmissive area TA. The auxiliary power contact portion AXC may serve to apply a common power voltage to a common electrode (cathode electrode or second electrode) formed across a front surface of the transparent display panel 110 in order to reduce the resistance of the common electrode. The auxiliary power contact portion AXC may include an auxiliary power electrode electrically connected to a common power line VSSL (or a second power line). The auxiliary power contact portion AXC may be configured to expose a portion of the auxiliary power electrode. The common electrode may be electrically connected to the auxiliary power electrode exposed through the auxiliary power contact portion AXC. The auxiliary power electrode may apply a common power voltage, applied from the common power line VSSL, to the common electrode. The auxiliary power contact portion AXC may be disposed in each transmissive area TA corresponding to each of the pixels P, or in any arbitrary plurality of transmissive areas TA, but embodiments of the present disclosure are not limited thereto.

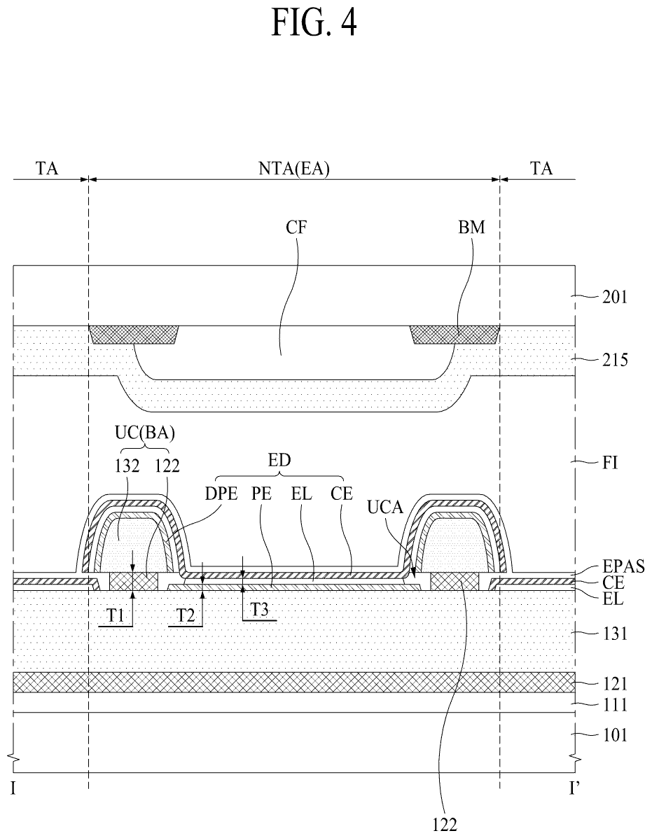

FIG. 4 is a cross-sectional view taken along line I-I′ of FIG. 3 according to an embodiment of the present disclosure.

Referring to FIG. 4, the transparent display panel 110 according to an embodiment of the present disclosure may include a non-transmissive area NTA including the light emission area EA, and a transmissive area TA. The transparent display panel 110 may include a first substrate 101 (or an array substrate) including a light emitting element ED and a second substrate 201 (or color filter substrate) including a color filter CF, and the first substrate 101 and the second substrate 201 may be bonded to each other by a connection member FI.

The first substrate 101 may include at least one signal line, a pixel circuit comprising at least one thin film transistor and a storage capacitor, and a light emitting element ED, all of which may be disposed for each of the plurality of subpixels SP1, SP2, SP3 and SP4. The second substrate 201 may include a plurality of color filters CF, which may be disposed for each of the plurality of subpixels SP1, SP2, SP3 and SP4. For example, the light emitting element ED included in each of the plurality of subpixels SP1, SP2, SP3 and SP4 may be disposed on the first substrate 101, and the color filter CF may be disposed on the second substrate 201 corresponding to the light emitting element ED. For example, the light emitting element ED on the first substrate 101 and the color filter CF on the second substrate 201 may be arranged to overlap each other, thereby forming an emission area EA.

A buffer layer 111 may be disposed on the first substrate 101. The buffer layer 111 may be configured to cover at least one signal line disposed on the first substrate 101. For example, the at least one signal line may include a pixel power line VDDL (or the first power line), a common power line VSSL (or the second power line), a reference line REFL, and data lines DL, but embodiments of the present disclosure are not limited thereto. At least one protective layer, at least one thin film transistor and an auxiliary power electrode may be disposed on the buffer layer 111. For example, at least one active layer of the thin film transistor and the auxiliary power electrode may be disposed on the buffer layer 111, with the at least one protective layer configured to cover the active layer and the auxiliary power electrode, but embodiments of the present disclosure are not limited thereto.

At least one signal line, at least one thin film transistor, and an auxiliary power electrode on the first substrate 101 may form a circuit layer (or a thin film transistor array layer). For example, the circuit layer may include at least one signal line and at least one thin film transistor disposed in a non-transmissive area NTA and may include an auxiliary power electrode disposed in a transmissive area TA.

A plurality of inorganic protective layers 121 and 122 and a plurality of organic protective layers 131 and 132 may be disposed on the circuit layer. For example, on the buffer layer 111 of the circuit layer, the plurality of inorganic protective layers 121 and 122 and the plurality of organic protective layers 131 and 132 may be alternately arranged in sequence. The plurality of inorganic protective layers 121 and 122 may include a first inorganic protective layer 121 and a second inorganic protective layer 122, and the plurality of organic protective layers 131 and 132 may include a first organic protective layer 131 and a second organic protective layer 132. Among the plurality of inorganic protective layers 121 and 122, the second inorganic protective layer 122 may be disposed between the plurality of organic protective layers 131 and 132, and among the plurality of organic protective layers 131 and 132, the first organic protective layer 131 may be disposed between the plurality of inorganic protective layers 121 and 122. For example, the first inorganic protective layer 121 may be disposed on the buffer layer 111, the first organic protective layer 131 may be disposed on the first inorganic protective layer 121, the second inorganic protective layer 122 may be disposed on the first organic protective layer 131, and the second organic protective layer 132 may be disposed on the second inorganic protective layer 122.

The first inorganic protective layer 121 may serve to protect at least one thin film transistor and the auxiliary power electrode of the circuit layer and may be formed of an inorganic insulating material. For example, the first inorganic protective layer 121 may be a passivation layer formed of a single layer or multi-layer. For example, the first inorganic protective layer 121 may be formed of a single layer or multi-layer, which includes silicon oxide (SiO_{X}), silicon nitride (SiN_{X}), silicon oxynitride (SiO_{X}N_{Y}), and aluminum oxide (Al₂O₃), but embodiments of the present disclosure are not limited thereto.

The first organic protective layer 131 may serve to planarize the step formed by at least one signal line, at least one thin film transistor, and the auxiliary power electrode included in the circuit layer, and may be formed of an organic insulating material. For example, the first organic protective layer 131 may be a planarization layer (or overcoat layer). For example, the first organic protective layer 131 may be formed of an organic material such as an acrylic resin, an epoxy resin, a phenolic resin, a polyamide resin, a polyimide resin, but embodiments of the present disclosure are not limited thereto.

The second inorganic protective layer 122 may be configured as a portion of a bank portion BA that defines an opening of a pixel electrode PE included in a light emitting element ED at the non-transmissive area NTA, and may be formed of an inorganic insulating material. For example, the second inorganic protective layer 122 may be formed of the same or different material as the first inorganic protective layer 121. For example, the second inorganic protective layer 122 may be formed of a single layer or multi-layer, which includes silicon oxide (SiO_{X}), silicon nitride (SiN_{X}), silicon oxynitride (SiO_{X}N_{Y}), and aluminum oxide (Al₂O₃), but embodiments of the present disclosure are not limited thereto.

The second organic protective layer 132 may be configured as a portion of the bank portion BA that defines the opening of the pixel electrode PE included in the light emitting element ED at the non-transmissive area NTA, and may be formed of an inorganic insulating material. For example, the second organic protective layer 132 may be formed of the same or different material as the first organic protective layer 131. For example, the second organic protective layer 132 may be formed of an organic material such as an acrylic resin, an epoxy resin, a phenolic resin, a polyamide resin, a polyimide resin, but embodiments of the present disclosure are not limited thereto.

The light emitting element ED may be disposed on the first organic protective layer 131 in the non-transmissive area (NTA). The light emitting element ED may include a pixel electrode PE (anode electrode or first electrode), a dummy pixel electrode DPE (or reflective electrode), a light emitting layer EL (or organic light emitting layer), a common electrode CE (cathode electrode or second electrode), and a bank portion BA.

The pixel electrode PE may be disposed on the first organic protective layer 131 for each of the plurality of subpixels SP1, SP2, SP3 and SP4. The pixel electrode PE may be electrically connected to a thin film transistor through a contact hole that passes through the first organic protective layer 131 and the first inorganic protective layer 121. For example, the pixel electrode PE may be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti). The pixel electrode PE may be an anode electrode of the light emitting element ED.

The bank portion BA may be disposed on the first organic protective layer 131. The bank portion BA may include an undercut structure UC formed of the second inorganic protective layer 122 and the second organic protective layer 132. The undercut structure UC may be configured to form the bank portion BA that defines the opening of the pixel electrode PE. The undercut structure UC forming the bank portion BA may include a single undercut region UCA.

The undercut structure UC may be configured to form an undercut region UCA on the first organic protective layer 131. The undercut structure UC may include a support pattern 122 and an eaves pattern 132. The support pattern 122 may be disposed at a certain distance from the pixel electrode PE disposed on the first organic protective layer 131. The support pattern 122 may be formed of the same material as the second inorganic protective layer 122. For example, the support pattern 122 may be configured by patterning the second inorganic protective layer 122. The support pattern 122 may be configured to have a first thickness T1. The pixel electrode PE may be configured to have a second thickness T2. For example, the second thickness T2 of the pixel electrode PE may have a lower height than the first thickness T1 of the support pattern 122. The eaves pattern 132 may be disposed on the support pattern 122 and configured to protrude from the support pattern 122. The eaves pattern 132 may be formed of the same material as the second organic protective layer 132. For example, the eaves pattern 132 may be formed by patterning the second organic protective layer 132. The undercut region UCA of the undercut structure UC may be formed below the eaves pattern 132 protruding from the support pattern 122.

The dummy pixel electrode DPE may be disposed on the eaves pattern 132 of the undercut structure UC. The dummy pixel electrode DPE may be an island pattern separated from the pixel electrode PE. The dummy pixel electrode DPE may be formed on at least a portion of the eaves pattern 132. For example, the dummy pixel electrode DPE may be formed on the entire surface of the eaves pattern 132. The dummy pixel electrode DPE may be symmetrically configured with respect to the pixel electrode PE. The dummy pixel electrode DPE may be made of the same material as the pixel electrode PE or a different material. For example, the dummy pixel electrode DPE may be made of the same material as the pixel electrode PE and may be simultaneously formed through the same process. The dummy pixel electrode DPE may be configured to be separated from the pixel electrode PE by the undercut region UCA of the undercut structure UC. The dummy pixel electrode DPE may be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti). The dummy pixel electrode DPE may be a reflective electrode of the light emitting element ED. The dummy pixel electrode DPE may perform the function of reflecting light emitted from the light emitting element ED in the upward direction. According to an embodiment of the present disclosure, the dummy pixel electrode DPE may enhance the light extraction efficiency of the light emitting element ED by converging, reflecting, and directing the light emitted from the light-emitting element ED.

The light emitting layer EL may be disposed on the pixel electrode PE and the bank portion BA. For example, the light emitting layer EL may be disposed on the pixel electrode PE and the dummy pixel electrode DPE on the undercut structure UC. The light emitting layer EL may be configured to have a third thickness T3. For example, the third thickness T3 of the light emitting layer EL may have a height lower than the first thickness T1 of the support pattern 122. The first thickness T1 of the support pattern 122 may be configured to have a height equal to or greater than the sum of the second thickness T2 of the pixel electrode PE and the third thickness T3 of the light emitting layer EL. The light emitting layer EL on the bank portion BA may be an island pattern separated from the light emitting layer EL on the pixel electrode PE. For example, the light emitting layer EL on the bank portion BA may be configured to be separated from the light emitting layer EL on the pixel electrode PE by the undercut region UCA of the undercut structure UC.

The common electrode CE may be disposed on the light emitting layer EL. The common electrode CE may be disposed in common across the plurality of subpixels SP1, SP2, SP3, and SP4. The common electrode CE may be disposed on the pixel electrodes PE and the light emitting layer EL, which are in contact with each other, to form the light emitting element ED. The common electrode CE on the bank portion BA may be connected to the common electrode CE on the pixel electrode PE and may be separated from the common electrode CE on the transmissive area TA. For example, the common electrode CE on the pixel electrode PE may be connected to the common electrode CE on the bank portion BA by the undercut area UCA of the undercut structure UC being covered by the thickness of the pixel electrode PE and the light emitting layer EL. The common electrode CE may be formed of a transparent conductive material (TCO) such as indium tin oxide (ITO) or indium zinc oxide (IZO) that is capable of transmitting light. The common electrode CE may also be formed of a semi-transmissive conductive material such as magnesium (Mg), silver (Ag), or an alloy of magnesium (Mg) and silver (Ag). For example, when the common electrode CE is formed of a semi-transmissive metal material, light emission efficiency may be increased by a micro cavity. The common electrode CE may be a cathode electrode of the light emitting element ED.

The first substrate 101 may further include an encapsulation layer EPAS. The encapsulation layer EPAS may be disposed on the non-transmissive area NTA and the transmissive area TA of the first substrate 101. The encapsulation layer EPAS may be disposed on the common electrode CE. For example, the encapsulation layer EPAS may be configured to cover the common electrode CE. The encapsulation layer EPAS may serve to prevent oxygen or moisture from being permeated into the light emitting element ED. For example, the encapsulation layer EPAS may include at least one inorganic material layer, and may further include at least one organic material layer, but embodiments of the present disclosure are not limited thereto.

The second substrate 201 (opposite substrate or color filter substrate) may include a plurality of color filters CF and a black matrix BM. The plurality of color filters CF may be disposed to correspond to each of the plurality of subpixels SP1, SP2, SP3 and SP4. The plurality of color filters CF may be formed of organic materials that transmit light of different colors. The black matrix BM may be disposed between the plurality of color filters CF and may be disposed between each color filter CF and the transmissive area TA. The black matrix BM may be disposed between the subpixels SP1, SP2, SP3 and SP4 and may prevent color mixing between adjacent subpixels SP1, SP2, SP3 and SP4. The black matrix BM may be disposed between the transmissive area TA and the plurality of subpixels SP1, SP2, SP3 and SP4 to prevent light emitted from each of the plurality of subpixels SP1, SP2, SP3 and SP4 from moving to the transmissive area TA. For example, the black matrix BM may include a material that absorbs light, for example, a black dye that absorbs all of light in a visible wavelength band.

The second substrate 201 may further include a top protective layer 215 that covers the color filter CF and the black matrix BM. The top protective layer 215 may serve to protect the color filter CF and the black matrix BM and may be formed of an organic insulating material. For example, the top protective layer 215 may be formed of an organic material such as an acrylic resin, an epoxy resin, a phenolic resin, a polyamide resin, a polyimide resin, but embodiments of the present disclosure are not limited thereto.

The connection member FI may be disposed between the first substrate 101 including the light emitting element ED and the second substrate 201 including the color filter CF. For example, the connection member FI may be a thermosetting resin or a UV curable resin, and may be made of an organic material having an adhesive property. For example, the connection member FI may include a material that absorbs hydrogen, but embodiments of the present disclosure are not limited thereto.

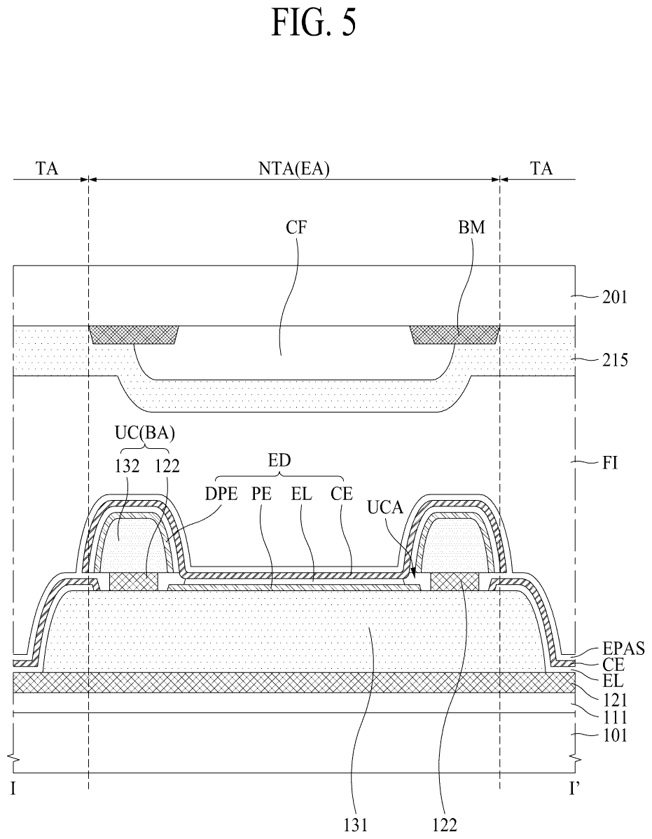

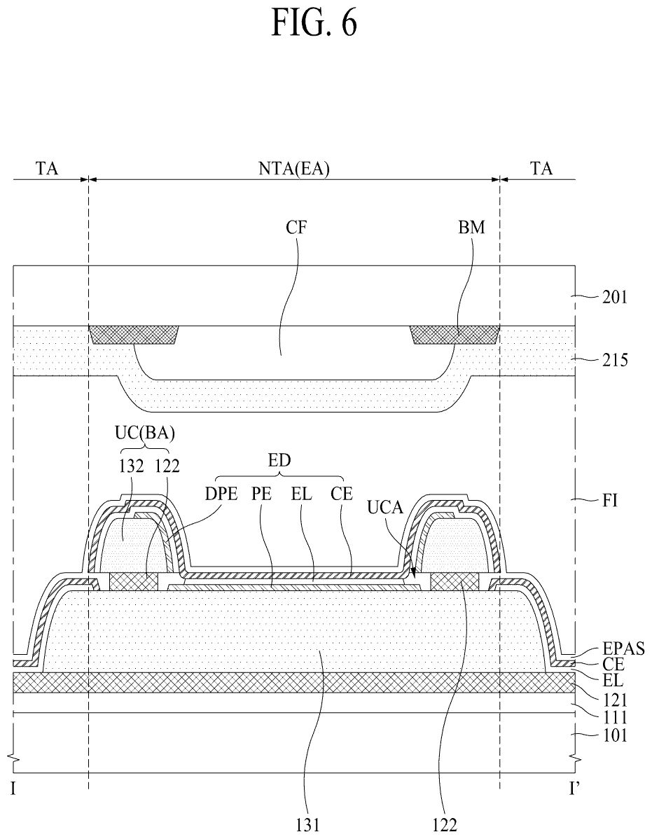

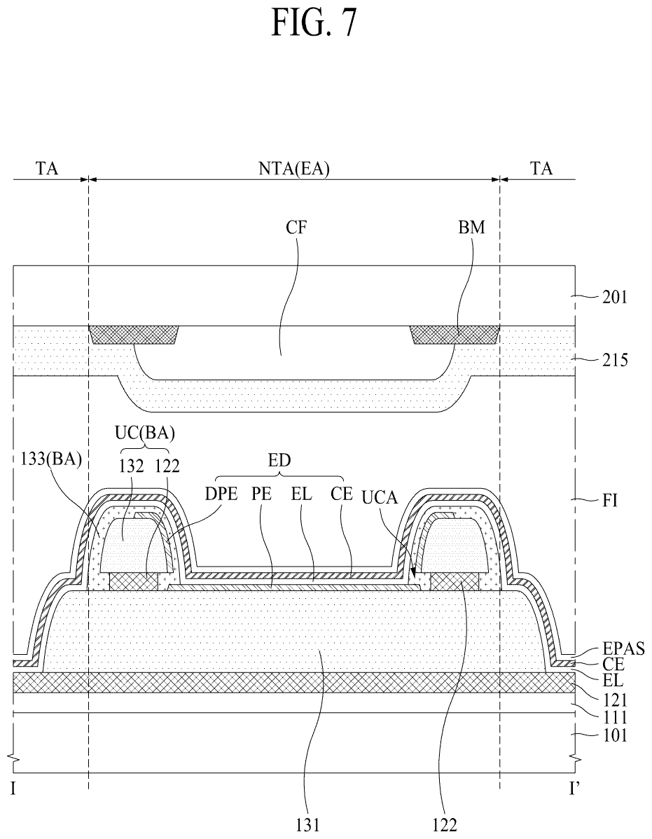

FIG. 5 is a cross-sectional view taken along line I-I′ of FIG. 3 according to another embodiment of the present disclosure. FIG. 6 is a cross-sectional view taken along line I-I′ of FIG. 3 according to another embodiment of the present disclosure. FIG. 7 is a cross-sectional view taken along line I-I′ of FIG. 3 according to another embodiment of the present disclosure. FIGS. 5 to 7 illustrate various embodiments in which a structure of the transmissive area TA and the bank portion BA in the transparent display panel 110, described with reference to FIGS. 1 to 4, is modified. In the following description referring to FIGS. 5 to 7, the same reference numerals will be used for the same components, except for the modified ones, and their redundant description will be omitted or briefly described.

Referring to FIGS. 5 to 7, the transparent display panel 110 according to another embodiment of the present disclosure may include a non-transmissive area NTA including the light emission area EA, and a transmissive area TA. The transparent display panel 110 may include a first substrate 101 (or an array substrate) including a light emitting element ED and a second substrate 201 (or color filter substrate) including a color filter CF, and the first substrate 101 and the second substrate 201 may be bonded to each other by a connection member FI.

On the first substrate 101, a buffer layer 111, a plurality of inorganic protective layers 121 and 122, and a plurality of organic protective layers 131 and 132 may be disposed. In the transmission area TA of the first substrate 101, at least some of the plurality of inorganic protective layers 121 and 122 and the plurality of organic protective layers 131 and 132 may not be disposed. For example, in the transmission area TA of the first substrate 101, the second inorganic protective layer 122 among the plurality of inorganic protective layers 121 and 122 and the second organic protective layer 132 among the plurality of organic protective layers 131 and 132 may not be disposed.

The first organic protective layer 131 according to another embodiment of the present disclosure may not be disposed in at least a portion of the transmission area TA to improve the light transmittance of the transmission area TA. For example, the first organic protective layer 131 may be disposed in the non-transmission area NTA and may be at least partially removed in the transmission area TA.

Referring to FIG. 6, the transparent display panel 110 according to another embodiment of the present disclosure may include a light emitting element ED disposed in the non-transmission area NTA. The light emitting element ED may include a pixel electrode PE (anode electrode or first electrode), a dummy pixel electrode DPE (or reflective electrode), a light emitting layer EL (or organic light emitting layer), a common electrode CE (cathode electrode or second electrode), and a bank portion BA.

The dummy pixel electrode DPE according to another embodiment of the present disclosure may be formed on at least a portion of the eaves pattern 132 of the undercut structure UC. For example, the dummy pixel electrode DPE may be formed on a portion of a surface of the eaves pattern 132. The dummy pixel electrode DPE may be configured by being partially patterned on the portion of the surface of the eaves pattern 132.

The dummy pixel electrode DPE may be symmetrically configured with respect to the pixel electrode PE. The dummy pixel electrode DPE may be disposed on the eaves pattern 132 adjacent to the pixel electrode PE, and at least a portion of the eaves pattern 132 adjacent to the transmission area TA may be removed. The dummy pixel electrode DPE may be formed of the same or different material as the pixel electrode PE. For example, the dummy pixel electrode DPE may be formed of the same material as the pixel electrode PE and may be formed simultaneously through the same process. The dummy pixel electrode DPE may be configured to be separated from the pixel electrode PE by the undercut area UCA of the undercut structure UC. The dummy pixel electrode DPE may have at least a portion removed from the eaves pattern 132 adjacent to the transmission area TA through a patterning process. The dummy pixel electrode DPE may have at least a portion removed from the eaves pattern 132 adjacent to the transmission area TA through a patterning process.

The dummy pixel electrode DPE according to another embodiment of the present disclosure may not be disposed on the eaves pattern 132 adjacent to the transmission area TA, and may be configured by patterning only a portion of the surface of the eaves pattern 132 adjacent to the corresponding pixel electrode PE, thereby may prevent light diffused from adjacent pixels or the transmission area TA from being re-reflected, and may minimize viewing angle crosstalk. Referring to FIG. 7, the transparent display panel 110 according to another embodiment of the present disclosure may include a light emitting element ED disposed in the non-transmission area NTA. The light emitting element ED may include a pixel electrode PE (anode electrode or first electrode), a dummy pixel electrode DPE (or reflective electrode), a light emitting layer EL (or organic light emitting layer), a common electrode CE (cathode electrode or second electrode), and a bank portion BA.

On the first substrate 101, a buffer layer 111, a plurality of inorganic protective layers 121 and 122, and a plurality of organic protective layers 131, 132 and 133 may be disposed. The plurality of organic protective layers 131, 132 and 133 may include a first organic protective layer 131, a second organic protective layer 132, and a third organic protective layer 133.

The bank portion BA according to another embodiment of the present disclosure may further include a cover pattern 133. For example, the cover pattern 133 may be formed of the same material as the third organic protective layer 133. The bank portion BA may include an undercut structure UC formed of the second inorganic protective layer 122 and the second organic protective layer 132, and a cover pattern 133 configured to cover the undercut structure UC.

The dummy pixel electrode DPE may be disposed between the undercut structure UC and the cover pattern 133. The cover pattern 133 may be configured to cover the undercut structure UC and the dummy pixel electrode DPE. The cover pattern 133 may have a width greater than a width of the undercut structure UC and may be configured to define an opening for the pixel electrode PE. For example, the cover pattern 133 may be configured to cover an edge portion of the pixel electrode PE, the undercut structure UC, and the dummy pixel electrode DPE.

The light emitting layer EL and the common electrode CE may be disposed on the pixel electrode PE and the bank portion BA. For example, the light emitting layer EL and the common electrode CE may be disposed on the pixel electrode PE and the cover pattern 133. The light emitting layer EL and the common electrode CE on the cover pattern 133 may be electrically connected with the light emitting layer EL and the common electrode CE on the pixel electrode PE. For example, the light emitting layer EL and the common electrode CE on the cover pattern 133 may be continuously connected with the light emitting layer EL and the common electrode CE on the pixel electrode PE.

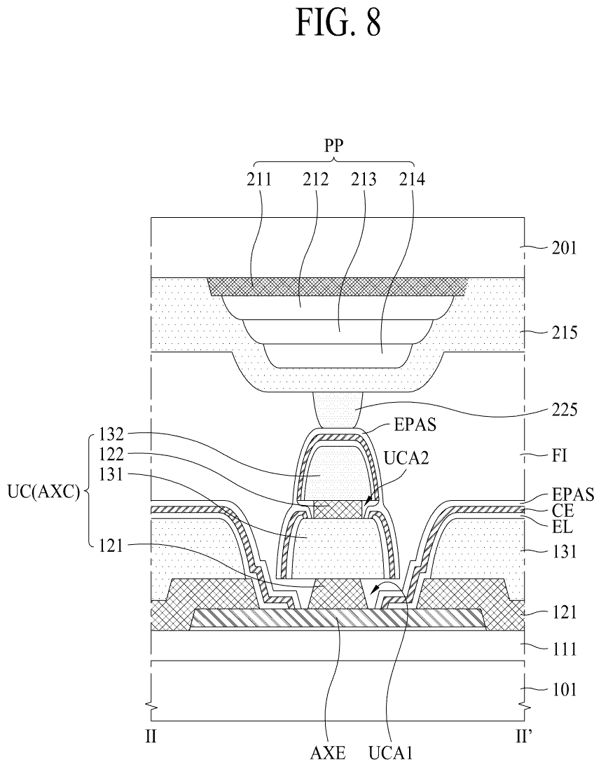

FIG. 8 is a cross-sectional view taken along line II-II′ of FIG. 3 according to an embodiment of the present disclosure. FIG. 8 illustrates an embodiment of an auxiliary power contact portion AXC disposed in the transmission area TA in the transparent display panel 110, described with reference to FIGS. 1 to 7. In the following description referring to FIG. 8, the same reference numerals will be used for the same components, except for the configuration of the auxiliary power contact portion AXC, and their redundant description will be omitted or briefly described.

Referring to FIG. 8, a transparent display panel 110 according to an embodiment of the present disclosure may include an auxiliary power contact portion AXC disposed in the transmission area TA.

On a first substrate 101 (or an array substrate), a buffer layer 111 may be disposed. On the buffer layer 111, an auxiliary power electrode AXE may be disposed. The auxiliary power electrode AXE may be disposed in the transmission area TA and may be electrically connected to a common power line VSSL (or a second power line). The auxiliary power electrode AXE may supply a common power voltage (or a second power voltage) to a common electrode CE of the light emitting element ED.

On the first substrate 101, at least one signal line, at least one thin film transistor, and the auxiliary power electrode AXE may form a circuit layer (or a thin film transistor array layer). For example, the circuit layer may include the auxiliary power electrode AXE disposed in the transmission area TA.

On the circuit layer, a plurality of inorganic protective layers 121 and 122 and a plurality of organic protective layers 131 and 132 may be disposed. The auxiliary power electrode AXE may include an auxiliary power contact portion AXC that includes one or more undercut areas UCA1 and UCA2 formed by a lower inorganic protective layer 121 and 122 and an upper organic protective layer 131 and 132, which are adjacent to each other among the plurality of inorganic protective layers 121 and 122 and the organic protective layers 131 and 132.

The auxiliary power contact portion AXC may include an undercut structure UC configured to expose a portion of the auxiliary power electrode AXE. The undercut structure UC may be formed of the plurality of inorganic protective layers 121 and 122 and the plurality of organic protective layers 131 and 132. For example, the undercut structure UC may be formed of a first inorganic protective layer 121, a first organic protective layer 131, a second inorganic protective layer 122, and a second organic protective layer 132. The undercut structure UC constituting the auxiliary power contact portion AXC may include a plurality of undercut areas UCA1 and UCA2.

The plurality of undercut areas UCA1 and UCA2 of the undercut structure UC may include a first undercut area UCA1 on the auxiliary power electrode AXE and a second undercut region UCA2 on a different layer from the first undercut region UCA1. For example, the second undercut area UCA2 of the undercut structure UC may be disposed in the same layer as the undercut area of the undercut structure constituting the bank portion BA disposed in the non-transmission area NTA. For example, the undercut structure UC may include a first support pattern 121, a first eaves pattern 131, a second support pattern 122, and a second eaves pattern 132.

The first support pattern 121 may be disposed on a portion of the auxiliary power electrode AXE and may be formed of the same material as the first inorganic protective layer 121. For example, the first support pattern 121 may be formed by patterning the first inorganic protective layer 121. The first eaves pattern 131 may be disposed on the first support pattern 121 and may be configured to protrude from the first support pattern 121. The first eaves pattern 131 may be formed of the same material as the first organic protective layer 131. For example, the first eaves pattern 131 may be formed by patterning the first organic protective layer 131. The first undercut area UCA1 may be formed below the first eaves pattern 131 protruding from the first support pattern 121.

The second support pattern 122 may be disposed on the first eaves pattern 131 and may be formed of the same material as the second inorganic protective layer 122. For example, the second support pattern 122 may be formed by patterning the second inorganic protective layer 122. The second eaves pattern 132 may be disposed on the second support pattern 122 and may be configured to protrude from the second support pattern 122. The second eaves pattern 132 may be formed of the same material as the second organic protective layer 132. For example, the second eaves pattern 132 may be formed by patterning the second organic protective layer 132. The second undercut area UCA2 may be formed below the second eaves pattern 132, which protrudes from the second support pattern 122. For example, the second undercut area UCA2 may be disposed between the first eaves pattern 131 and the second eaves pattern 132.

The auxiliary power electrode AXE may be exposed by the first undercut area UCA1 of the undercut structure UC. For example, a portion of the auxiliary power electrode AXE may be exposed by the first undercut area UCA1. An exposed portion of the auxiliary power electrode AXE may directly contact the common electrode CE of the light emitting element ED and be electrically connected to the common electrode CE. According to an embodiment of the present disclosure, the undercut structure UC constituting the auxiliary power contact portion AXC may be configured as a double structure protruding in an upward direction toward the second substrate 201, thereby performing a function of a gap spacer that maintains a uniform cell gap between the first substrate 101 and the second substrate 201. Also, the undercut structure UC of the auxiliary power contact portion AXC according to an embodiment of the present disclosure includes the undercut areas UCA1 and UCA2 of a double structure, thereby effectively preventing moisture infiltration caused by cracks in the encapsulation layer EPAS, which may occur while the undercut structure UC serves as a gap spacer, through the undercut areas UCA1 and UCA2 of the double structure.

The second substrate 201 (opposite substrate or color filter substrate) may include an upper protruding pattern portion PP disposed to overlap with the undercut structure UC constituting the auxiliary power contact portion AXC on the first substrate 101. The upper protruding pattern portion PP may include a plurality of protruding patterns 211, 212, 213 and 214, which are formed of the same material as at least a portion of a plurality of color filters CF and a black matrix BM. For example, the plurality of protruding patterns 211, 212, 213 and 214 may include a first protruding pattern 211 formed of the same material as the black matrix BM, a second protruding pattern 212 formed of the same material as a first color filter among the plurality of color filters CF, a third protruding pattern 213 formed of the same material as a second color filter among the plurality of color filters CF, and a fourth protruding pattern 214 formed of the same material as a third color filter among the plurality of color filters CF.

The second substrate 201 may include upper protective layers 215 and 225 disposed on the upper protruding pattern portion PP. The upper protective layers 215 and 225 may include a first upper protective layer 215 and a second upper protective layer 225. The first upper protective layer 215 may be configured to cover the upper protruding pattern portion PP. The first upper protective layer 215 may serve to protect the color filter CF and the black matrix BM constituting the upper protruding pattern portion PP and may be formed of an organic insulating material. The second upper protective layer 225 may be disposed on the first upper protective layer 215, which overlaps with the upper protruding pattern portion PP. The second upper protective layer 225 may be configured to have a narrower width than the upper protruding pattern portion PP. The second upper protective layer 225 may be configured to have a width narrower or wider than the second eaves pattern 132 of the undercut structure UC disposed on the first substrate 101. For example, as shown in FIG. 8, the second upper protective layer 225 may be configured to have a width narrower than the second eaves pattern 132. The second upper protective layer 225 may be formed of the same or different material as the first upper protective layer 215. For example, the second upper protective layer 225 may be formed of an organic insulating material. According to an embodiment of the present disclosure, the upper protruding pattern portion PP and the upper protective layers 215 and 225 are configured as a structure protruding in a downward direction toward the first substrate 101, thereby performing a function of a gap spacer that maintains a uniform cell gap between the first substrate 101 and the second substrate 201.

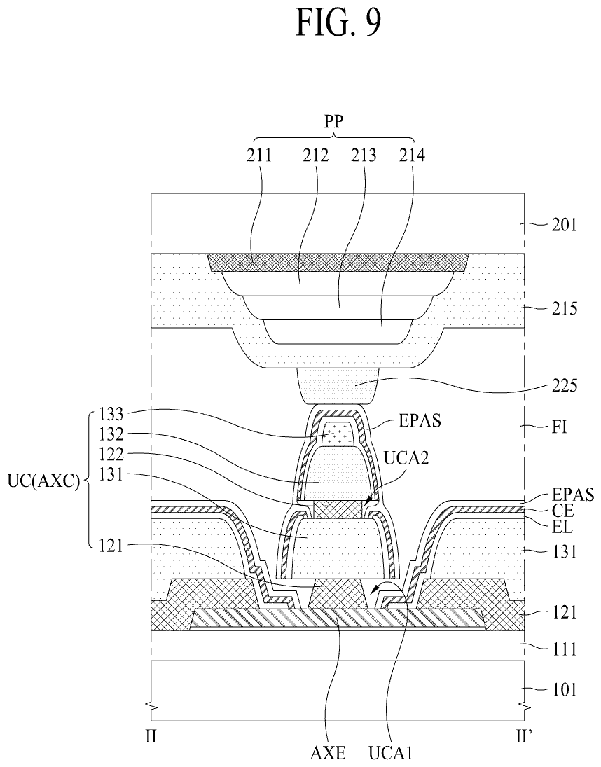

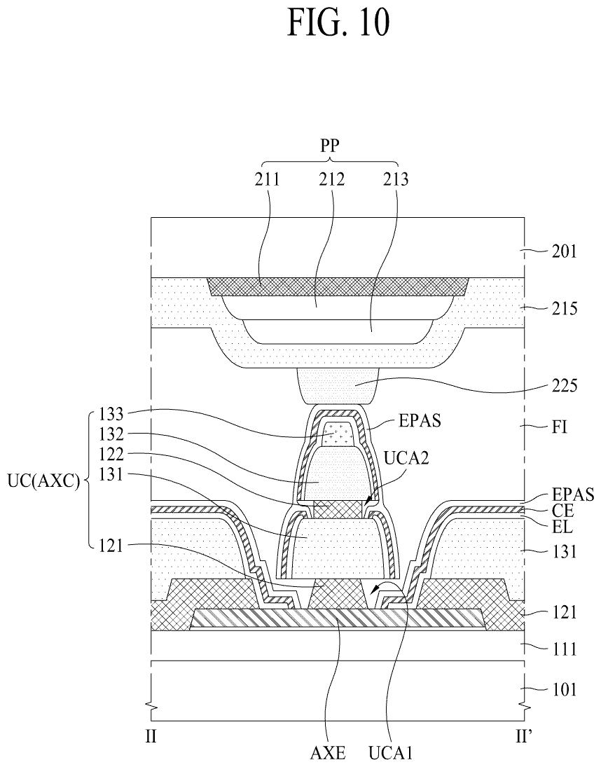

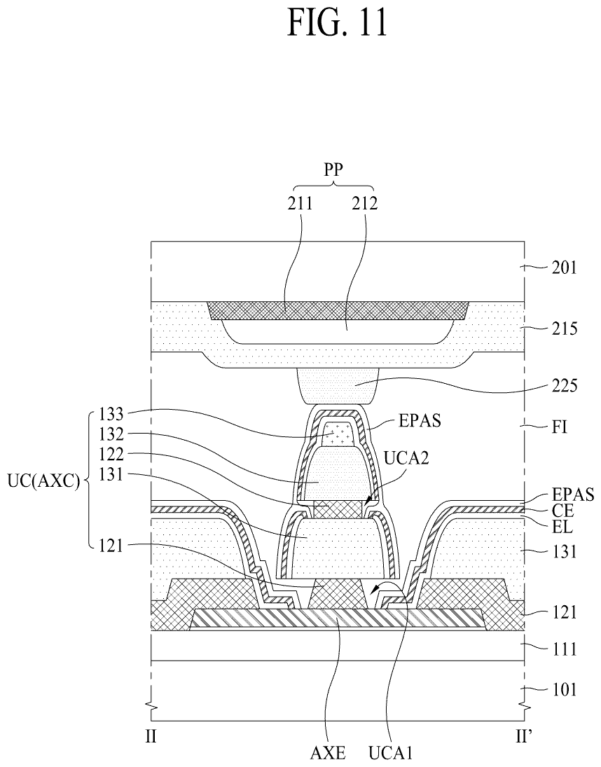

FIG. 9 is a cross-sectional view taken along line II-II′ of FIG. 3 according to another embodiment of the present disclosure. FIG. 10 is a cross-sectional view taken along line II-II′ of FIG. 3 according to another embodiment of the present disclosure. FIG. 11 is a cross-sectional view taken along line II-II′ of FIG. 3 according to another embodiment of the present disclosure. FIGS. 9 to 11 illustrate various embodiments in which a structure of the auxiliary power contact portion AXC of the transparent display panel 110, described with reference to FIG. 8, is modified. In the following description referring to FIGS. 9 to 11, the same reference numerals will be used for the same components, except for the modified ones, and their redundant description will be omitted or briefly described.

Referring to FIG. 9, a transparent display panel 110 according to another embodiment of the present disclosure may include an auxiliary power contact portion AXC disposed in the transmission area TA.

On the first substrate 101 (or an array substrate), a buffer layer 111, a plurality of inorganic protective layers 121 and 122, and a plurality of organic protective layers 131, 132 and 133 may be disposed. The plurality of organic protective layers 131, 132 and 133 may include a first organic protective layer 131, a second organic protective layer 132, and a third organic protective layer 133.

The auxiliary power contact portion AXC according to an embodiment of the present disclosure may further include a protruding pattern 133 formed of the same material as the third organic protective layer 133. The auxiliary power contact portion AXC may include an undercut structure UC formed of the plurality of inorganic protective layers 121 and 122 and the plurality of organic protective layers 131 and 132, and a protruding pattern 133 configured to extend from the undercut structure UC.

The protruding pattern 133 may have a smaller width than a top surface of the undercut structure UC and may be configured to protrude upward from the top surface of the undercut structure UC. For example, the protruding pattern 133 may be disposed on the second eaves pattern 132 of the undercut structure UC. The protruding pattern 133 may have a smaller width than the second eaves pattern 132 and may be configured to protrude upward from the second eaves pattern 132.

The second substrate 201 (counter substrate or color filter substrate) may include upper protective layers 215 and 225 disposed on the upper protruding pattern portion PP. The upper protective layers 215 and 225 may include a first upper protective layer 215 and a second upper protective layer 225. The second upper protective layer 225 may be configured to have a width narrower or wider than the protruding pattern 133 of the auxiliary power contact portion AXC disposed on the first substrate 101. For example, as shown in FIG. 9, the second upper protective layer 225 may be configured to have a width wider than the protruding pattern 133.

The protruding pattern 133 according to another embodiment of the present disclosure may adjust a distance of a cell gap between the first substrate 101 and the second substrate 201. For example, the protruding pattern 133 may increase the distance of the cell gap between the first substrate 101 and the second substrate 201.

Referring to FIGS. 10 and 11, the second substrate 201 (counter substrate or color filter substrate) of the transparent display panel 110 according to another embodiment of the present disclosure may include an upper protruding pattern portion PP disposed to overlap with the undercut structure UC constituting the auxiliary power contact portion AXC on the first substrate 101. The upper protruding pattern portion PP may include a plurality of protruding patterns 211, 212 and 213 formed of the same material as at least a portion of a plurality of color filters CF and a black matrix BM. For example, as shown in FIG. 10, the upper protruding pattern portion PP may include a first protruding pattern 211 formed of the same material as the black matrix BM, a second protruding pattern 212 formed of the same material as a first color filter among the plurality of color filters CF, and a third protruding pattern 213 formed of the same material as a second color filter among the plurality of color filters CF. For example, as shown in FIG. 11, the upper protruding pattern portion PP may include a first protruding pattern 211 formed of the same material as the black matrix BM and a second protruding pattern 212 formed of the same material as the first color filter among the plurality of color filters CF.

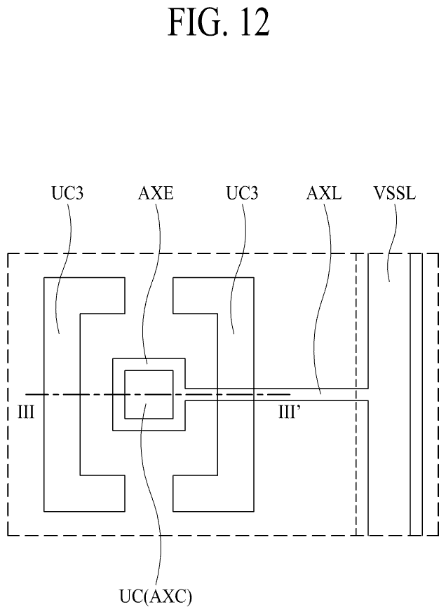

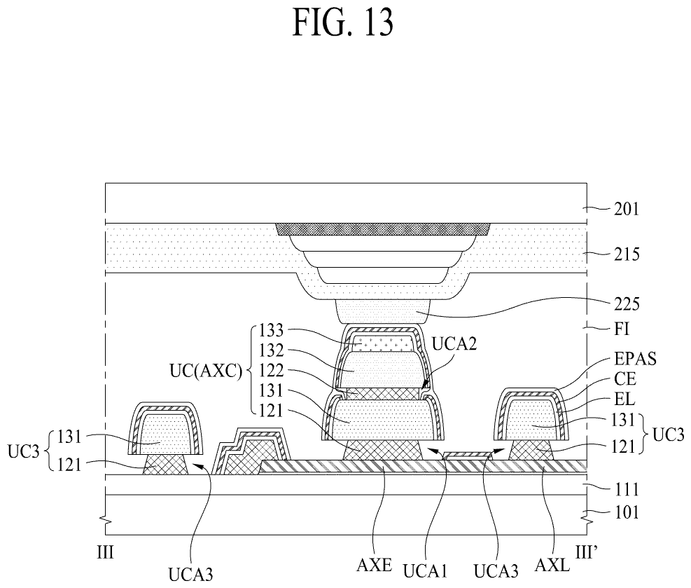

FIG. 12 illustrates a region B shown in FIG. 3 according to another embodiment of the present disclosure. FIG. 13 is a cross-sectional view taken along line III-III′ of FIG. 12 according to another embodiment of the present disclosure. FIGS. 12 and 13 illustrate embodiments in which an undercut structure UC3 is additionally configured around the auxiliary power contact portion AXC in the transparent display panel 110 described with reference to FIGS. 1 to 11. In the following description referring to FIGS. 12 and 13, the same reference numerals will be used for the same components, except for the added ones, and their redundant description will be omitted or briefly described.

Referring to FIGS. 12 and 13, the transparent display panel 110 according to another embodiment of the present disclosure may further include an undercut structure UC3 formed on at least a portion of a surrounding perimeter of the auxiliary power contact portion AXC disposed in the transmission area TA.

The undercut structure UC3 may be formed of a first inorganic protective layer 121 and a first organic protective layer 131. The undercut structure UC3 may include an undercut area UCA3.

The undercut structure UC3 may be disposed on at least a portion of the surrounding perimeter of the auxiliary power contact portion AXC. The undercut structure UC3 may be configured symmetrically with the auxiliary power contact portion AXC interposed therebetween. For example, the undercut structure UC3 may be configured in a “C” shape. The undercut structure UC3 may be disposed on one side and the other side in a second direction (or the X-axis direction) of the auxiliary power contact portion AXC. The undercut structures UC3 disposed on one side and the other side respectively may be disposed to be spaced apart from each other. The undercut structure UC3 may be disposed on a buffer layer 111. A portion of the undercut structure UC3 may be disposed to overlap with an auxiliary power connection line AXL, which is connected between an auxiliary power electrode AXE and a common power line VSSL. According to an embodiment of the present disclosure, the undercut structure UC3 may protect the auxiliary power contact portion AXC, which may function as a gap spacer capable of maintaining a uniform cell gap. The undercut structure UC3 may prevent a crack in an encapsulation layer EPAS disposed on the auxiliary power contact portion AXC from spreading to the surrounding area when the crack occurs in the encapsulation layer EPAS.

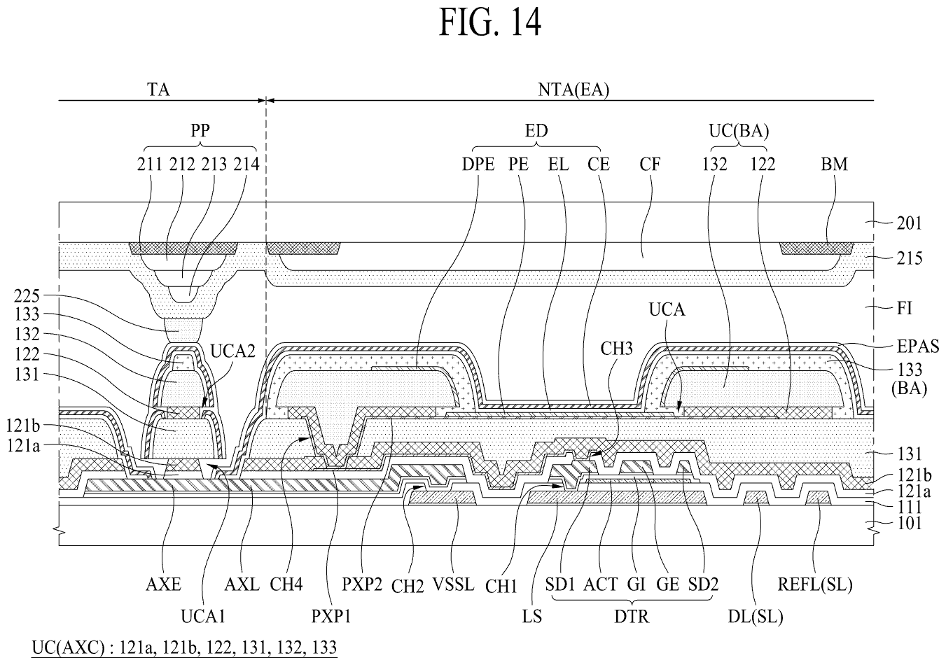

FIG. 14 illustrates a transparent display apparatus according to another embodiment of the present disclosure. FIG. 14 illustrates the overall configuration of the transparent display panel 110 described with reference to FIGS. 1 to 13. Hereinafter, the same reference numerals will be used for the same components as previously described, and their redundant description will be omitted or briefly described.

Referring to FIG. 14, the transparent display panel 110 according to another embodiment of the present disclosure may include a non-transmissive area NTA including the light emission area EA, and a transmissive area TA. The transparent display panel 110 may include a first substrate 101 (or an array substrate) including a light emitting element ED and a second substrate 201 (or a color filter substrate) including a color filter CF, and the first substrate 101 and the second substrate 201 may be bonded to each other by a connection member FI.

The first substrate 101 according to another embodiment of the present disclosure may include a light shielding layer LS, at least one signal line SL, such as a data line DL and a reference line REFL, at least one power line, such as a common power line VSSL, a buffer layer 111, an auxiliary power electrode AXE, an auxiliary power connection line AXL, at least one thin film transistor, such as a driving transistor DTR, at least one first inorganic protective layer, such as a first passivation layer 121a and a second passivation layer 121b, a first organic protective layer 131 (a planarization layer or an overcoat layer), a light emitting element ED, a bank portion BA, and an auxiliary power contact portion AXC.

A light shielding layer LS, at least one signal line SL, such as a data line DL and a reference line REFL, and at least one power line, such as a common power line VSSL, may be disposed on the first substrate 101.

The light shielding layer LS may be disposed to overlap the driving transistor DTR. The light shielding layer LS may overlap an active layer ACT of the driving transistor DTR. For example, the light shielding layer LS may be disposed to overlap a channel region of the active layer ACT in a plane view. The light shielding layer LS may serve to block external light from entering the active layer ACT. Also, at least one signal line SL, such as a data line DL and a reference line REFL, and at least one power line, such as a common power line VSSL, containing the same material in the same layer as the light shielding layer LS may be disposed on the first substrate 101.

The light shielding layer LS, at least one signal line SL, such as a data line DL and a reference line REFL, and at least one power line, such as a common power line VSSL, may be formed of one or more layers. For example, the light shielding layer LS, the at least one signal line SL, and the common power line VSSL may include an upper metal layer and a lower metal layer, where the lower metal layer may prevent an underside of the upper metal layer from corroding. For example, the lower metal layer may be formed of a material with a lower oxidation rate and is good in anticorrosion compared to the upper metal layer, and may include a molybdenum (Mo), a titanium (Ti), or a Mo-Ti alloy (MoTi). Also, the upper metal layer may include copper (Cu) which is metal having lower resistivity than that of the lower metal layer. Also, the upper metal layer may be configured to have a thickness which is greater than that of the lower metal layer, so as to decrease a total resistance, but embodiments of the present disclosure are not limited thereto.

On the first substrate 101, the buffer layer 111 may be disposed to cover the light shielding layer LS, the at least one signal line SL, and the common power line VSSL. The buffer layer 111 may be formed by stacking a single layer or multi-layer. For example, the buffer layer 111 may be formed of a single layer or multi-layer, which includes silicon oxide (SiO_{X}), silicon nitride (SiN_{X}), silicon oxynitride (SiO_{X}N_{Y}), and aluminum oxide (Al₂O₃), but embodiments of the present disclosure are not limited thereto. The buffer layer 111 may be formed all over an upper surface of the first substrate 101 so as to block ions or impurities diffused from the first substrate 101 and prevent or at least reduce the penetration of water into the light emitting element ED through the first substrate 101.

On the buffer layer 111, an auxiliary power electrode AXE, an auxiliary power connection line AXL, at least one thin film transistor, such as a driving transistor DTR, and a storage capacitor may be disposed. For example, the auxiliary power electrode AXE may be disposed in the transmission area TA on the buffer layer 111, and the driving transistor DTR may be disposed in the non-transmission area NTA on the buffer layer 111.

The driving transistor DTR may include an active layer ACT, a gate electrode GE, which is overlapped with the active layer ACT with a gate insulating layer GI in between, a first electrode SD1 (or a first source/drain electrode) and a second electrode SD2 (or a second source/drain electrode).

The active layer ACT of the driving transistor DTR may be formed of a silicon-based or oxide-based semiconductor material and may be disposed on the buffer layer 111. The active layer ACT may include a channel region overlapping with the gate electrode GE, and a source region and a drain region connected to the first electrode SD1 and the second electrode SD2.

The gate insulating layer GI may be disposed on the active layer ACT. The gate insulating layer GI may be disposed between the active layer ACT and the gate electrode GE. The gate insulating layer GI may serve to insulate between the active layer ACT and the gate electrode GE, may be formed of an inorganic insulating material. The gate insulating layer GI may be formed of a single layer or multi-layer, which includes silicon oxide (SiO_{X}), silicon nitride (SiN_{X}), silicon oxynitride (SiO_{X}N_{Y}), and aluminum oxide (Al₂O₃), but embodiments of the present disclosure are not limited thereto.

The gate insulation layer GI may have the gate electrode GE, the first electrode SD1, and the second electrode SD2 disposed thereon. For example, the gate electrode GE may be formed of the same material as the first electrode SD1 and the second electrode SD2 in the same layer, but embodiments of the present disclosure are not limited thereto. For example, the gate electrode GE, the first electrode SD1, and the second electrode SD2 may be formed of copper (Cu), molybdenum (Mo), aluminum (Al), chromium (Cr), gold (Au), titanium (Ti), nickel (Ni), neodymium (Nd), tantalum (Ta), tungsten (W), or an alloy thereof. One of the first electrode SD1 and the second electrode SD2 may be connected to the light shielding layer LS through a first contact hole CH1 that passes through the gate insulation layer GI and the buffer layer 111. For example, the first electrode SD1 may be electrically connected to the light shielding layer LS through the first contact hole CH1.

A transmissive area TA on the gate insulation layer GI may be disposed on an auxiliary power electrode AXE. The auxiliary power electrode AXE may be formed of the same material as the gate electrode GE in the same layer. The auxiliary power electrode AXE may be electrically connected to a common power line VSSL (or a second power line). On the gate insulation layer GI, an auxiliary power connection line AXL may be disposed to connect the auxiliary power electrode AXE and the common power line VSSL. The auxiliary power electrode AXE and the auxiliary power connection line AXL may be integrally formed. The auxiliary power connection line AXL may be connected to the common power line VSSL through a second contact hole CH2 passing through the gate insulation layer GI and the buffer layer 111. For example, the auxiliary power connection line AXL may electrically connect between the auxiliary power electrode AXE and the common power line VSSL through the second contact hole CH2. For example, the gate insulation layer GI may be patterned together with the gate electrode GE, the first electrode SD1, the second electrode SD2, the auxiliary power electrode AXE, and the auxiliary power connection line AXL. The gate insulation layer GI may be disposed below the gate electrode GE, the first electrode SD1, the second electrode SD2, the auxiliary power electrode AXE, and the auxiliary power connection line AXL.

At least one first inorganic protective layer, such as a first passivation layer 121a and a second passivation layer 121b, may be disposed on a circuit layer, which includes at least one thin film transistor, such as a driving transistor DTR, disposed in a non-transmissive area NTA and an auxiliary power electrode AXE disposed in a transmissive area TA. The at least one first inorganic protective layer 121a and 121b may include a first passivation layer 121a and a second passivation layer 121b. For example, the first passivation layer 121a may be disposed on the buffer layer 111, where the gate electrode GE, the first electrode SD1, the second electrode SD2, the auxiliary power electrode AXE, and the auxiliary power connection line AXL are disposed. The second passivation layer 121b may be disposed on the first passivation layer 121a.

A first organic protective layer 131, a second inorganic protective layer 122, a second organic protective layer 132, and a third organic protective layer 133 may be disposed on at least one inorganic protective layer 121a and 121b. For example, the second inorganic protective layer 122, the second organic protective layer 132, and the third organic protective layer 133 disposed in the non-transmissive area NTA may form a bank portion BA that defines an opening of the pixel electrode PE. The at least one of the first inorganic protective layers 121a and 121b, the first organic protective layer 131, the second inorganic protective layer 122, the second organic protective layer 132, and the third organic protective layer 133 disposed in the transmissive area TA may form an auxiliary power contact portion AXC that exposes a portion of the auxiliary power electrode AXE.

The transparent display panel 110 according to another embodiment of the present disclosure may further include a pixel electrode connection pattern PXP1 and PXP2 connecting between the pixel electrode PE and the driving transistor DTR. The pixel electrode connection pattern PXP1 and PXP2 may electrically connect between the pixel electrode PE and the first electrode SD1 of the driving transistor DTR. For example, the pixel electrode connection pattern PXP1 and PXP2 may be formed integrally with the pixel electrode PE and may electrically connect to the first electrode SD1 of the driving transistor DTR through a contact hole passing through at least one first inorganic protective layer 121a and 121b and the first organic protective layer 131, which are disposed between the pixel electrode PE and the first electrode SD1 of the driving transistor DTR, but embodiments of the present disclosure are not limited thereto.

Referring to FIG. 14, the pixel electrode connection pattern PXP1 and PXP2 according to another embodiment of the present disclosure may include a first pixel electrode connection pattern PXP1 and a second pixel electrode connection pattern PXP2. The first pixel electrode connection pattern PXP1 may be disposed between the first passivation layer 121a and the second passivation layer 121b. The first pixel electrode connection pattern PXP1 may be connected to the first electrode SD1 of the driving transistor DTR through a third contact hole CH3 passing through the first passivation layer 121a. The second pixel electrode connection pattern PXP2 may be disposed between the pixel electrode PE and the first organic protective layer 131. The second pixel electrode connection pattern PXP2 may be connected to the first pixel electrode connection pattern PXP1 through a fourth contact hole CH4 passing through the first organic protective layer 131 and the second passivation layer 121b.

The second substrate 201 according to another embodiment of the present disclosure may include a color filter CF, a black matrix BM, an upper protruding pattern portion PP, and an upper protective layer 215 and 225. For example, the upper protruding pattern portion PP may be formed of the same material as at least a portion of the color filter CF and the black matrix BM. For example, the upper protective layers 215 and 225 may include a first upper protective layer 215 configured to cover the upper protruding pattern portion PP and a second upper protective layer 225 overlapping with the upper protruding pattern portion PP. According to another embodiment of the present disclosure, the auxiliary power contact portion AXC disposed on the first substrate 101 and the upper protruding pattern portion PP and the upper protective layers 215 and 225 disposed on the second substrate 201 may serve as a gap spacer that maintains a uniform cell gap between the first substrate 101 and the second substrate 201.

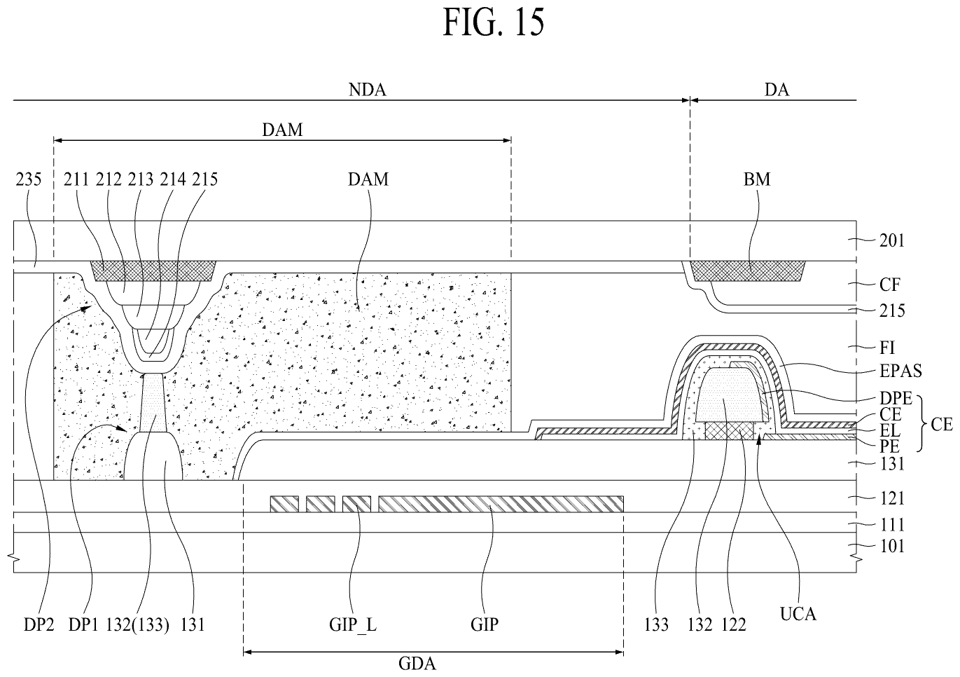

FIGS. 15 to 18 illustrate a non-display area of a transparent display apparatus according to another embodiment of the present disclosure. FIGS. 15 to 18 illustrate various embodiments of the configuration of the non-display area in the transparent display apparatus described with reference to FIGS. 1 to 14. In the following description referring to FIGS. 15 to 18, the same reference numerals will be used for the same components, except for the configuration of the non-display area, and their redundant description will be omitted or briefly described.

Referring to FIGS. 15 to 18, the transparent display panel 110 according to another embodiment of the present disclosure may include a display area DA and a non-display area NDA.

The display area DA is the area where an image is displayed and may include a non-transmissive area NTA in which a plurality of subpixels SP1, SP2, SP3 and SP4 are disposed, and a transmissive area TA.

The non-display area NDA is the area where an image is not displayed and may be disposed around the display area DA. For example, the non-display area NDA may be configured to surround the display area DA. The non-display area NDA may be an edge region surrounding the display area DA.

The non-display area NDA may include a pad area where pads are disposed, and a gate drive area GDA, in which a gate driver circuit GIP and a gate driver line GIP_L, which constitute at least one gate driver 205, are disposed.

In the gate drive area GDA, the gate driver circuit GIP and the gate driver line GIP_L may be disposed on a buffer layer 111 of a first substrate 101. A first inorganic protective layer 121 and a first organic protective layer 131 may be disposed on the gate driver circuit GIP and the gate driver line GIP_L. For example, the first organic protective layer 131 may be disposed to extend from the display area DA to the gate drive area GDA. The first inorganic protective layer 121 may be disposed to extend from the display area DA to the edge of the first substrate 101, but embodiments of the present disclosure are not limited thereto.

The non-display area NDA may further include a dam pattern portion DAM surrounding the edge between the first substrate 101 and the second substrate 201.

The dam pattern portion DAM may be configured in a closed-loop shape surrounding the periphery of the display area DA in the non-display area NDA. For example, the dam pattern portion DAM may be configured in a rectangular shape in a plane, but embodiments of the present disclosure are not limited thereto. For example, the dam pattern portion DAM may serve to seal the side between the first substrate 101 and the second substrate 201 from the external environment, and may be formed of an adhesive member or transparent adhesive, but embodiments of the present disclosure are not limited thereto.

The dam pattern portion DAM may include a first dam pattern DP1 and a second dam pattern DP2. The first dam pattern DP1 may be disposed on the first substrate 101 and may be formed of the same material as at least a portion of a plurality of inorganic protective layers 121 and 122, and a plurality of organic protective layers 131, 132 and 133. The second dam pattern DP2 may be disposed on the second substrate 201 and may be formed of the same material as at least a portion of a plurality of color filters CF.

Referring to FIG. 15, the transparent display panel 110 according to another embodiment of the present disclosure may include a dam pattern portion DAM disposed in the non-display area NDA.

The dam pattern portion DAM may be disposed in the non-display area NDA to overlap with a gate driving area GDA. For example, the dam pattern portion DAM may be disposed between the edge ends of the first substrate 101 and the second substrate 201 and the display area DA. At least a portion of the dam pattern portion DAM may be disposed to overlap with the gate driving area GDA.

The dam pattern portion DAM may include a first dam pattern DP1 disposed on the first substrate 101 and a second dam pattern DP2 disposed on the second substrate 201.

The first dam pattern DP1 may be disposed on a first inorganic protective layer 121 of the first substrate 101. The first dam pattern DP1 may be formed of the same material as at least a portion of a first organic protective layer 131, a second inorganic protective layer 122, a second organic protective layer 132, and a third organic protective layer 133, which are disposed on the first inorganic protective layer 121. For example, as shown in FIG. 15, the first dam pattern DP1 may be formed of the first organic protective layer 131 and the second organic protective layer 132. Alternatively, the first dam pattern DP1 may be formed of the first organic protective layer 131 and the third organic protective layer 133.

The second dam pattern DP2 may be disposed on the second substrate 201. The second dam pattern DP2 may be formed of the same material as at least a portion of a plurality of color filters CF disposed on the second substrate 201. For example, the second dam pattern DP2 may be formed of the plurality of color filters CF and a black matrix BM. For example, as shown in FIG. 15, the second dam pattern DP2 may include a first pattern 211 formed of the same material as the black matrix BM, a second pattern 212 formed of the same material as a first color filter of the plurality of color filters CF, a third pattern 213 formed of the same material as a second color filter of the plurality of color filters CF, a fourth pattern 214 formed of the same material as a third color filter of the plurality of color filters CF, and a fifth pattern 215 formed of the same material as a first upper protective layer 215.

According to another embodiment of the present disclosure, the second substrate 201 may further include a third upper protective layer 235 in the non-display area NDA. For example, the third upper protective layer 235 may be configured to cover the second dam pattern DP2 disposed on the second substrate 201. The third upper protective layer 235 may be formed of an inorganic insulating material. For example, the third upper protective layer 235 may be formed of a single layer or multi-layer, which includes silicon oxide (SiO_{X}), silicon nitride (SiN_{X}), silicon oxynitride (SiO_{X}N_{Y}), and aluminum oxide (Al₂O₃), but embodiments of the present disclosure are not limited thereto. According to another embodiment of the present disclosure, by disposing the third upper protective layer 235 formed of an inorganic insulating material in the non-display area NDA of the second substrate 201, contact between the dam pattern portion DAM and the organic protective layer may be blocked, thereby improving the moisture permeability reliability of the dam pattern portion DAM.

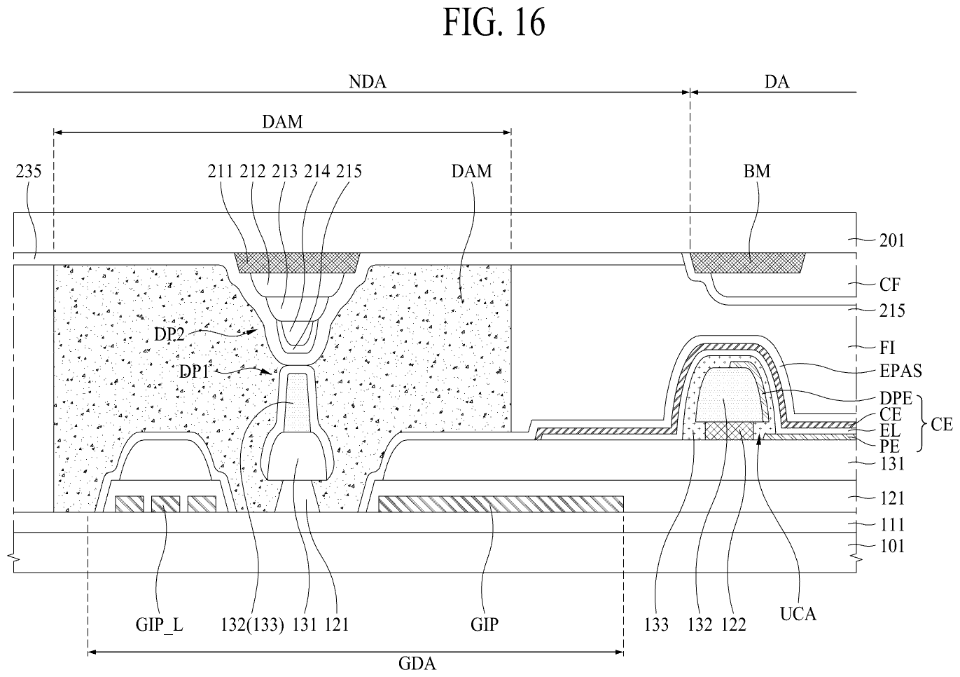

Referring to FIG. 16, the transparent display panel 110 according to another embodiment of the present disclosure may be configured such that a gate drive circuit GIP and a gate drive line GIP_L, which are disposed in a gate drive area GDA, are spaced apart from each other.

The dam pattern portion DAM may be disposed in the non-display area NDA to overlap with the gate drive area GDA. For example, the dam pattern portion DAM may be disposed between the edge ends of the first substrate 101 and the second substrate 201 and the display area DA. At least a portion of the dam pattern portion DAM may be disposed to overlap with the gate drive area GDA.

The dam pattern portion DAM may include a first dam pattern DP1 disposed on the first substrate 101 and a second dam pattern DP2 disposed on the second substrate 201.

The first dam pattern DP1 may be disposed in the gate driving area GDA. For example, the first dam pattern DP1 may be disposed between the gate driving circuit GIP and the gate driving line GIP_L in the gate driving area GDA.

The first dam pattern DP1 may be disposed on a buffer layer 111 of the first substrate 101. The first dam pattern DP1 may be formed of the same material as at least a portion of a first inorganic protective layer 121, a first organic protective layer 131, a second inorganic protective layer 122, a second organic protective layer 132, and a third organic protective layer 133. For example, as shown in FIG. 16, the first dam pattern DP1 may be formed of the first inorganic protective layer 121, the first organic protective layer 131, and the second organic protective layer 132. Alternatively, the first dam pattern DP1 may be formed of the first inorganic protective layer 121, the first organic protective layer 131, and the third organic protective layer 133. For example, the first dam pattern DP1 may include an undercut region formed of the first organic protective layer 131 and the first inorganic protective layer 121. An encapsulation layer EPAS may be disposed on the first dam pattern DP1.

According to another embodiment of the present disclosure, the first and second dam patterns DP1 and DP2 may be disposed in the gate driving area GDA, thereby distributing the load caused by the lamination of the first substrate 101 and the second substrate 201 inside the dam pattern portion DAM, and since a separate structure outside the dam pattern portion DAM may be eliminated, the transparent display apparatus capable of implementing a narrow bezel may be provided. Also, the first dam pattern DP1 according to another embodiment of the present disclosure may include the undercut region, thereby effectively preventing moisture infiltration through the undercut region due to cracks in the encapsulation layer EPAS caused by the lamination of the first dam pattern DP1 and the second dam pattern DP2.

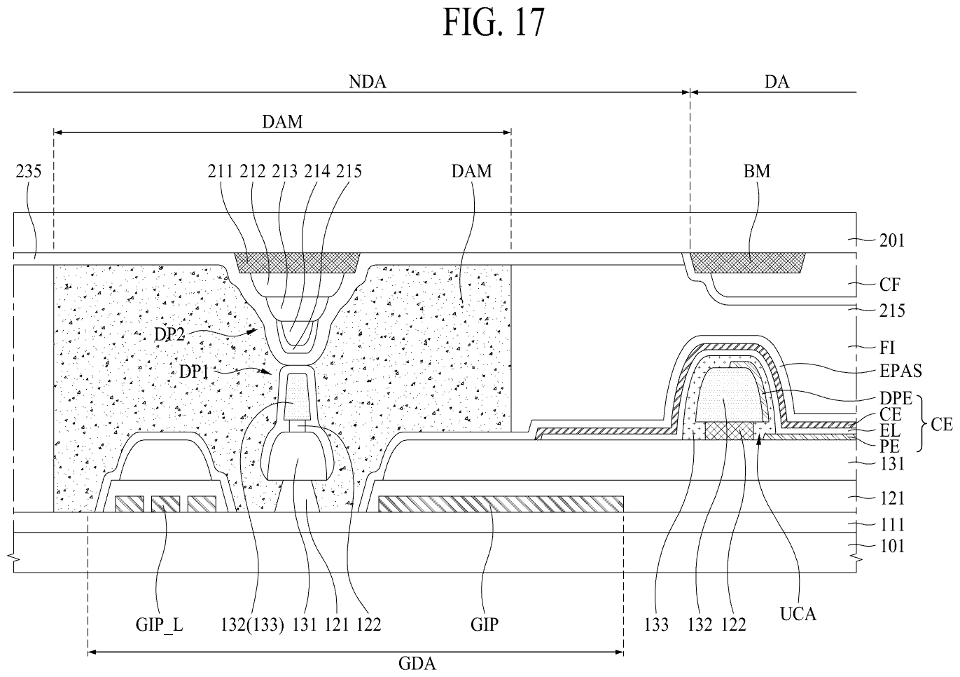

Referring to FIG. 17, the first dam pattern DP1 according to another embodiment of the present disclosure may be formed of a first inorganic protective layer 121, a first organic protective layer 131, a second inorganic protective layer 122, and a second organic protective layer 132. For example, the first dam pattern DP1 may include a first undercut region formed of the first organic protective layer 131 and the first inorganic protective layer 121, and a second undercut region formed of the second organic protective layer 132 and the second inorganic protective layer 122. Alternatively, the first dam pattern DP1 may be formed of the first inorganic protective layer 121, the first organic protective layer 131, the second inorganic protective layer 122, and the third organic protective layer 133. For example, the first dam pattern DP1 may include the first undercut region formed of the first organic protective layer 131 and the first inorganic protective layer 121, and the second undercut region formed of the third organic protective layer 133 and the second inorganic protective layer 122. An encapsulation layer EPAS may be disposed on the first dam pattern DP1.

According to another embodiment of the present disclosure, the first and second dam patterns DP1 and DP2 may be disposed in the gate driving area GDA, thereby distributing the load caused by the lamination of the first substrate 101 and the second substrate 201 inside the dam pattern portion DAM, and since a separate structure outside the dam pattern portion DAM may be eliminated, the transparent display apparatus capable of implementing a narrow bezel may be provided. Also, the first dam pattern DP1 according to another embodiment of the present disclosure may include an undercut region with a dual structure, thereby more effectively preventing moisture infiltration through the dual structure undercut region due to cracks in the encapsulation layer EPAS caused by the lamination of the first dam pattern DP1 and the second dam pattern DP2.

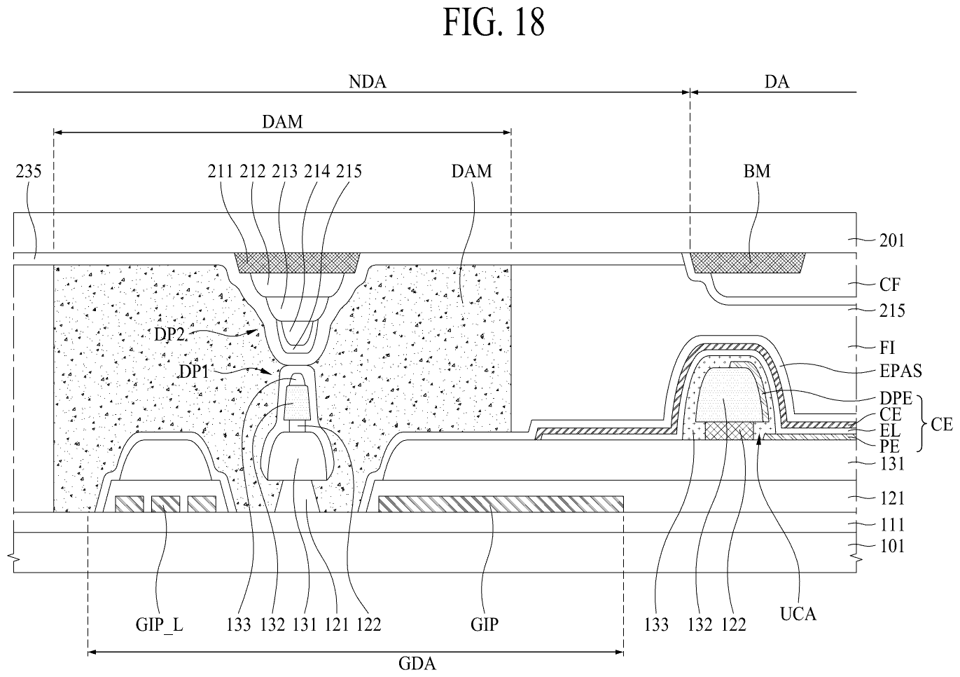

Referring to FIG. 18, the first dam pattern DP1 according to another embodiment of the present disclosure may be formed of a first inorganic protective layer 121, a first organic protective layer 131, a second inorganic protective layer 122, a second organic protective layer 132, and a third organic protective layer 133. For example, the first dam pattern DP1 may include a first undercut region formed of the first organic protective layer 131 and the first inorganic protective layer 121, and a second undercut region formed of the second organic protective layer 132 and the second inorganic protective layer 122. An encapsulation layer EPAS may be disposed on the first dam pattern DP1.

According to another embodiment of the present disclosure, the transparent display panel 110 may maintain the cell gap between the first substrate 101 and the second substrate 201 through a dam pattern portion DAM, which includes the first dam pattern DP1 disposed on the first substrate 101 and the second dam pattern DP2 disposed on the second substrate 201. This configuration allows for the elimination of a separate dam spacer and prevents the occurrence of cracks in the encapsulation layer EPAS caused by compression of the conventional dam spacer. The transparent display panel 110 according to another embodiment of the present disclosure may maintain the cell gap between the first substrate 101 and the second substrate 201 through the dam pattern portion DAM, which includes the first dam pattern DP1 disposed on the first substrate 101 and the second dam pattern DP2 disposed on the second substrate 201, thereby a separate dam spacer may be eliminated, and the occurrence of cracks in the encapsulation layer EPAS due to a pressing phenomenon caused by the conventional dam spacer may be prevented. As a result, the gap between the dam pattern portion DAM and the display area DA may be reduced, thereby enabling the provision of the transparent display apparatus capable of implementing a narrow bezel. Also, the first and second dam patterns DP1 and DP2 according to another embodiment of the present disclosure may be disposed in the gate driving area GDA, thereby distributing the load caused by the lamination of the first substrate 101 and the second substrate 201 inside the dam pattern portion DAM, and since a separate structure outside the dam pattern portion DAM may be eliminated, the transparent display apparatus capable of implementing a narrow bezel may be provided. Also, the first dam pattern DP1 according to another embodiment of the present disclosure may include an undercut region of a dual structure, thereby effectively preventing moisture infiltration through the dual structure undercut region due to cracks in the encapsulation layer EPAS caused by the lamination of the first dam pattern DP1 and the second dam pattern DP2.

A transparent display apparatus according to one or more embodiments of the present disclosure will be described below.

A transparent display apparatus according to one or more embodiments of the present disclosure may include a substrate, a transmissive area, a non-transmissive area including a light emission area in which a light emitting element is disposed, a circuit layer on the substrate, the circuit layer having an auxiliary power electrode disposed in the transmissive area and at least one thin film transistor disposed in the non-transmissive area, a plurality of inorganic protective layers and a plurality of organic protective layers on the circuit layer, and an undercut structure including at least one undercut region formed by a lower inorganic protective layer and an upper organic protective layer, which are adjacent to each other among the plurality of inorganic protective layers and the plurality of organic protective layers.

According to one or more embodiments of the present disclosure, the plurality of inorganic protective layers and the plurality of organic protective layers may be alternately arranged in sequence.

According to one or more embodiments of the present disclosure, one of the plurality of inorganic protective layers may be between the plurality of organic protective layers, and one of the plurality of organic protective layers is between the plurality of inorganic protective layers.

According to one or more embodiments of the present disclosure, the undercut structure may include a first undercut structure configured to form a contact portion that exposes a portion of the auxiliary power electrode, and a second undercut structure configured to form a bank portion that defines an opening of a pixel electrode included in the light emitting element.

According to one or more embodiments of the present disclosure, the first undercut structure may include a plurality of undercut regions, and the second undercut structure may include a single undercut region.

According to one or more embodiments of the present disclosure, the first undercut structure may include a first undercut region on the auxiliary power electrode, and a second undercut region in a different layer from the first undercut region, and the second undercut structure may include a third undercut region in the same layer as the second undercut region.

According to one or more embodiments of the present disclosure, the plurality of inorganic protective layers and the plurality of organic protective layers may include a first inorganic protective layer on the circuit layer, a first organic protective layer on the first inorganic protective layer, a second inorganic protective layer on the first organic protective layer, and a second organic protective layer on the second inorganic protective layer.

According to one or more embodiments of the present disclosure, the undercut structure may include a first undercut structure formed of the first inorganic protective layer, the first organic protective layer, the second inorganic protective layer, and the second organic protective layer, and a second undercut structure formed of the second inorganic protective layer and the second organic protective layer.

According to one or more embodiments of the present disclosure, the first undercut structure may include a first support pattern disposed on a portion of the auxiliary power electrode and formed of the same material as the first inorganic protective layer, a first eaves pattern disposed on the first support pattern, protruding from the first support pattern, and formed of the same material as the first organic protective layer, a second support pattern disposed on the first eaves pattern and formed of the same material as the second inorganic protective layer, and a second eaves pattern disposed on the second support pattern, protruding from the second support pattern, and formed of the same material as the second organic protective layer.

According to one or more embodiments of the present disclosure, the first undercut structure may include a first undercut region below the first eaves pattern protruding from the first support pattern, and a second undercut region below the second eaves pattern protruding from the second support pattern.

According to one or more embodiments of the present disclosure, the second undercut structure may include a third support pattern disposed at a certain distance from the pixel electrode included in the light emitting element on the first organic protective layer and formed of the same material as the second inorganic protective layer, and a third eaves pattern disposed on the third support pattern, protruding from the third support pattern, and formed of the same material as the second organic protective layer.

According to one or more embodiments of the present disclosure, the second undercut structure may include a third undercut region below the third eaves pattern protruding from the third support pattern.

According to one or more embodiments of the present disclosure, the light emitting element may further include a dummy pixel electrode on the third eaves pattern, and the dummy pixel electrode may be an island pattern separated from the pixel electrode.

According to one or more embodiments of the present disclosure, the dummy pixel electrode may be formed on at least a portion of the third eaves pattern.

According to one or more embodiments of the present disclosure, the plurality of inorganic protective layers and the plurality of organic protective layers may further include a third organic protective layer. The transparent display apparatus may further include a protruding pattern formed of the same material as the third organic protective layer and protruding from the first undercut structure, and a cover pattern formed of the same material as the third organic protective layer and covering an edge portion of the pixel electrode included in the light emitting element on the first organic protective layer and the second undercut structure.

According to one or more embodiments of the present disclosure, the protruding pattern may be configured to have a width narrower than an uppermost surface of the first undercut structure and to protrude in an upward direction from the uppermost surface.

According to one or more embodiments of the present disclosure, the cover pattern may be configured to have a width wider than a width of the second undercut structure and to define an opening of the pixel electrode.

According to one or more embodiments of the present disclosure, the non-transmissive area may include the first organic protective layer, and the transmissive area may be where at least a portion of the first organic protective layer is removed.

According to one or more embodiments of the present disclosure, the transparent display apparatus may further include a third undercut structure formed on at least a portion of a surrounding perimeter of the first undercut structure.

According to one or more embodiments of the present disclosure, the third undercut structure may be formed of the same material as the first inorganic protective layer and the first organic protective layer.

According to one or more embodiments of the present disclosure, the light emitting element may include a pixel electrode disposed on the first organic protective layer and electrically connected to the at least one thin film transistor, a bank portion disposed on the first organic protective layer, including the second undercut structure, and defining an opening of the pixel electrode, a dummy pixel electrode disposed on the bank portion, an organic light emitting layer disposed on the pixel electrode and the dummy pixel electrode, and a common electrode disposed on the organic light emitting layer.

According to one or more embodiments of the present disclosure, a thickness of the pixel electrode may have a lower height than a thickness of the second inorganic protective layer.

According to one or more embodiments of the present disclosure, a thickness of the organic light emitting layer may have a lower height than a thickness of the second inorganic protective layer.

According to one or more embodiments of the present disclosure, the organic light emitting layer on the bank portion may be an island pattern separated from the organic light emitting layer on the pixel electrode.

According to one or more embodiments of the present disclosure, the common electrode on the bank portion may be connected to the common electrode on the pixel electrode and may be separated from the common electrode on the transmissive area.

According to one or more embodiments of the present disclosure, the plurality of inorganic protective layers and the plurality of organic protective layers may further include a third organic protective layer. The transparent display apparatus may further include a cover pattern formed of the same material as the third organic protective layer and covering the bank portion, the dummy pixel electrode may be disposed between the bank portion and the cover pattern, and the organic light emitting layer and the common electrode may be disposed on the cover pattern and electrically connected to the organic light emitting layer and the common electrode disposed on the pixel electrode.

According to one or more embodiments of the present disclosure, the transparent display apparatus may further include a pixel electrode connection pattern connecting the pixel electrode and the at least one thin film transistor.

According to one or more embodiments of the present disclosure, the pixel electrode connection pattern may be connected to the at least one thin film transistor through a contact hole passing through the first organic protective layer and the first inorganic protective layer.

According to one or more embodiments of the present disclosure, the first inorganic protective layer may include a first passivation layer and a second passivation layer, the pixel electrode connection pattern may include a first pixel electrode connection pattern between the first passivation layer and the second passivation layer, and connected to the at least one thin film transistor through a first contact hole passing through the first passivation layer, and a second pixel electrode connection pattern between the pixel electrode and the first organic protective layer, and connected to the first pixel electrode connection pattern through a second contact hole passing through the first organic protective layer and the second passivation layer.

According to one or more embodiments of the present disclosure, the transparent display apparatus may further include an opposite substrate disposed to face the substrate, including a plurality of color filters disposed to correspond to the light emission area, the opposite substrate may be disposed to overlap with the undercut structure disposed on the auxiliary power electrode, and include an upper protruding pattern formed of the same material as at least a portion of the plurality of color filters.

According to one or more embodiments of the present disclosure, the transparent display apparatus may further include a top protective layer covering the plurality of color filters and the upper protruding pattern on the opposite substrate.

According to one or more embodiments of the present disclosure, the top protective layer may include a first top protective layer covering the plurality of color filters and the upper protruding pattern, and a second top protective layer disposed on the first top protective layer, which overlaps with the upper protruding pattern, and which has a width narrower than a width of the upper protruding pattern.

According to one or more embodiments of the present disclosure, the substrate may include a display area and a non-display area surrounding the display area, and the transparent display apparatus may further include a dam pattern portion between the substrate and the opposite substrate and disposed in the non-display area of the substrate.

According to one or more embodiments of the present disclosure, the dam pattern portion may include a first dam pattern disposed on the substrate and formed of the same material as at least a portion of the plurality of inorganic protective layers and the plurality of organic protective layers, and a second dam pattern disposed on the opposite substrate, overlapping the first dam pattern, and formed of the same material as at least a portion of the plurality of color filters.

According to one or more embodiments of the present disclosure, the first dam pattern may include one or more undercut regions formed by a lower inorganic protective layer and an upper organic protective layer, which are adjacent to each other among the plurality of inorganic protective layers and the plurality of organic protective layers.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A transparent display apparatus, comprising:
a substrate;
a transmissive area;
a non-transmissive area including a light emission area in which a light emitting element is disposed;
a circuit layer on the substrate, the circuit layer having an auxiliary power electrode disposed in the transmissive area and at least one thin film transistor disposed in the non-transmissive area;
a plurality of inorganic protective layers and a plurality of organic protective layers on the circuit layer; and
an undercut structure including at least one undercut region formed by a lower inorganic protective layer and an upper organic protective layer, which are adjacent to each other among the plurality of inorganic protective layers and the plurality of organic protective layers.

2. The transparent display apparatus of claim 1, wherein the plurality of inorganic protective layers and the plurality of organic protective layers are alternately arranged in sequence.

3. The transparent display apparatus of claim 1, wherein one of the plurality of inorganic protective layers is between the plurality of organic protective layers, and one of the plurality of organic protective layers is between the plurality of inorganic protective layers.

4. The transparent display apparatus of claim 1, wherein the undercut structure includes:
a first undercut structure configured to form a contact portion that exposes a portion of the auxiliary power electrode; and
a second undercut structure configured to form a bank portion that defines an opening of a pixel electrode included in the light emitting element.

5. The transparent display apparatus of claim 4, wherein the first undercut structure includes a plurality of undercut regions, and the second undercut structure includes a single undercut region.

6. The transparent display apparatus of claim 4, wherein the first undercut structure includes:
a first undercut region on the auxiliary power electrode; and
a second undercut region in a different layer from the first undercut region, and
wherein the second undercut structure includes a third undercut region in a same layer as the second undercut region.

7. The transparent display apparatus of claim 1, wherein the plurality of inorganic protective layers and the plurality of organic protective layers include:
a first inorganic protective layer on the circuit layer;
a first organic protective layer on the first inorganic protective layer;
a second inorganic protective layer on the first organic protective layer; and
a second organic protective layer on the second inorganic protective layer.

8. The transparent display apparatus of claim 7, wherein the undercut structure includes:
a first undercut structure formed of the first inorganic protective layer, the first organic protective layer, the second inorganic protective layer, and the second organic protective layer; and
a second undercut structure formed of the second inorganic protective layer and the second organic protective layer.

9. The transparent display apparatus of claim 8, wherein the first undercut structure includes:
a first support pattern disposed on a portion of the auxiliary power electrode and formed of a same material as the first inorganic protective layer;
a first eaves pattern disposed on the first support pattern, protruding from the first support pattern, and formed of a same material as the first organic protective layer;
a second support pattern disposed on the first eaves pattern and formed of a same material as the second inorganic protective layer; and
a second eaves pattern disposed on the second support pattern, protruding from the second support pattern, and formed of a same material as the second organic protective layer.

10. The transparent display apparatus of claim 9, wherein the first undercut structure includes:
a first undercut region below the first eaves pattern protruding from the first support pattern; and
a second undercut region below the second eaves pattern protruding from the second support pattern.

11. The transparent display apparatus of claim 8, wherein the second undercut structure includes:
a third support pattern disposed at a certain distance from the pixel electrode included in the light emitting element on the first organic protective layer and formed of a same material as the second inorganic protective layer; and
a third eaves pattern disposed on the third support pattern, protruding from the third support pattern, and formed of a same material as the second organic protective layer.

12. The transparent display apparatus of claim 11, wherein the second undercut structure includes a third undercut region below the third eaves pattern protruding from the third support pattern.

13. The transparent display apparatus of claim 11, wherein the light emitting element further includes a dummy pixel electrode on the third eaves pattern, and
wherein the dummy pixel electrode is an island pattern separated from the pixel electrode.

14. The transparent display apparatus of claim 13, wherein the dummy pixel electrode is formed on at least a portion of the third eaves pattern.

15. The transparent display apparatus of claim 8, wherein the plurality of inorganic protective layers and the plurality of organic protective layers further include a third organic protective layer, and
wherein the transparent display apparatus further comprises:
a protruding pattern formed of a same material as the third organic protective layer and protruding from the first undercut structure; and
a cover pattern formed of the same material as the third organic protective layer and covering an edge portion of the pixel electrode included in the light emitting element on the first organic protective layer and the second undercut structure.

16. The transparent display apparatus of claim 15, wherein the protruding pattern is configured to have a width narrower than an uppermost surface of the first undercut structure and to protrude in an upward direction from the uppermost surface.

17. The transparent display apparatus of claim 15, wherein the cover pattern is configured to have a width wider than a width of the second undercut structure and to define an opening of the pixel electrode.

18. The transparent display apparatus of claim 8, wherein the non-transmissive area includes the first organic protective layer, and
wherein the transmissive area is where at least a portion of the first organic protective layer is removed.

19. The transparent display apparatus of claim 18, further comprising a third undercut structure formed on at least a portion of a surrounding perimeter of the first undercut structure.

20. The transparent display apparatus of claim 19, wherein the third undercut structure is formed of a same material as the first inorganic protective layer and the first organic protective layer.

21. The transparent display apparatus of claim 8, wherein the light emitting element includes:
a pixel electrode disposed on the first organic protective layer and electrically connected to the at least one thin film transistor;
a bank portion disposed on the first organic protective layer, including the second undercut structure, and defining an opening of the pixel electrode;
a dummy pixel electrode disposed on the bank portion;
an organic light emitting layer disposed on the pixel electrode and the dummy pixel electrode; and
a common electrode disposed on the organic light emitting layer.

22. The transparent display apparatus of claim 21, wherein a thickness of the pixel electrode has a lower height than a thickness of the second inorganic protective layer.

23. The transparent display apparatus of claim 21, wherein a thickness of the organic light emitting layer has a lower height than a thickness of the second inorganic protective layer.

24. The transparent display apparatus of claim 21, wherein the organic light emitting layer on the bank portion is an island pattern separated from the organic light emitting layer on the pixel electrode.

25. The transparent display apparatus of claim 21, wherein the common electrode on the bank portion is connected to the common electrode on the pixel electrode and is separated from the common electrode on the transmissive area.

26. The transparent display apparatus of claim 21, wherein the plurality of inorganic protective layers and the plurality of organic protective layers further include a third organic protective layer,
wherein the transparent display apparatus further comprises a cover pattern formed of a same material as the third organic protective layer and covering the bank portion,
wherein the dummy pixel electrode is disposed between the bank portion and the cover pattern, and
wherein the organic light emitting layer and the common electrode are disposed on the cover pattern and electrically connected to the organic light emitting layer and the common electrode disposed on the pixel electrode.

27. The transparent display apparatus of claim 21, further comprising a pixel electrode connection pattern connecting the pixel electrode and the at least one thin film transistor.

28. The transparent display apparatus of claim 27, wherein the pixel electrode connection pattern is connected to the at least one thin film transistor through a contact hole passing through the first organic protective layer and the first inorganic protective layer.

29. The transparent display apparatus of claim 27, wherein the first inorganic protective layer includes a first passivation layer and a second passivation layer,
wherein the pixel electrode connection pattern includes:
a first pixel electrode connection pattern between the first passivation layer and the second passivation layer, and connected to the at least one thin film transistor through a first contact hole passing through the first passivation layer; and
a second pixel electrode connection pattern between the pixel electrode and the first organic protective layer, and connected to the first pixel electrode connection pattern through a second contact hole passing through the first organic protective layer and the second passivation layer.

30. The transparent display apparatus of claim 1, further comprising an opposite substrate disposed to face the substrate, including a plurality of color filters disposed to correspond to the light emission area,
wherein the opposite substrate is disposed to overlap with the undercut structure disposed on the auxiliary power electrode, and includes an upper protruding pattern formed of a same material as at least a portion of the plurality of color filters.

31. The transparent display apparatus of claim 30, further comprising a top protective layer covering the plurality of color filters and the upper protruding pattern on the opposite substrate.

32. The transparent display apparatus of claim 30, wherein the top protective layer includes:
a first top protective layer covering the plurality of color filters and the upper protruding pattern; and
a second top protective layer disposed on the first top protective layer, which overlaps with the upper protruding pattern, and which has a width narrower than a width of the upper protruding pattern.

33. The transparent display apparatus of claim 30, wherein the substrate includes a display area and a non-display area surrounding the display area, and
wherein the transparent display apparatus further comprises a dam pattern portion between the substrate and the opposite substrate and disposed in the non-display area of the substrate.

34. The transparent display apparatus of claim 33, wherein the dam pattern portion includes:
a first dam pattern disposed on the substrate and formed of a same material as at least a portion of the plurality of inorganic protective layers and the plurality of organic protective layers; and
a second dam pattern disposed on the opposite substrate, overlapping the first dam pattern, and formed of a same material as at least a portion of the plurality of color filters.

35. The transparent display apparatus of claim 34, wherein the first dam pattern includes one or more undercut regions formed by a lower inorganic protective layer and an upper organic protective layer, which are adjacent to each other among the plurality of inorganic protective layers and the plurality of organic protective layers.
